(19) United States
(12) Patent Application Publication
(10) Pub. No.: US 2023/0236996 A1
(43) Pub. Date: Jul. 27, 2023

(54) SINGLE ENDED PATTERN DEPENDENT AND POWER SUPPLY BASED REFERENCE VOLTAGE ADAPTATION TO IMPROVE DATA EYE MARGIN

(71) Applicant: Intel Corporation, Santa Clara, CA (US)

(72) Inventors: Ruchir SARASWAT, Portland, OR (US); Sriram VENKATESAN, Fremont, CA (US); Pradeep KARAMCHETI, Visakhapatnam (IN); Mohit VERMA, Bangalore (IN)

(21) Appl. No.: 18/129,748

(22) Filed: Mar. 31, 2023

(51) Int. Cl. G06F 13/16; G06T 1/60; G06F 1/26

(52) U.S. Cl. CPC G06F 13/1668; G06T 1/60; G06F 1/266

(57) ABSTRACT

Inter-device communication with a pulse-amplitude modulation (PAM) signal can have at least two data eyes with different Vref levels. A physical interface (PHY) can be trained for the PAM signal by training a first data eye separately from the second data eye. The training can include adjusting the first Vref level separately from the second Vref level to center each reference voltage on its respective data eye.

### TECHNICAL FIELD

Descriptions are generally related to device interconnect, and more particular descriptions are related to training the data eye margin.

### BACKGROUND OF THE INVENTION

Graphics memory has moved from non-return to zero (NRZ) communication to pulse amplitude modulation (PAM) communication. PAM communication refers to communication having multiple voltage levels for signaling, where transitions between the different voltage levels create multiple data eyes.

In practical systems, the multiple data eyes are unsymmetrical, and training of the voltage references at the vertical center of the data eyes leads to direct current (DC) offsets relative to the common mode voltage. Such offsets in the reference voltages leads to errors in the detection between the different data eyes. When different devices are connected over a communication channel and have different power distribution paths, there is non-optimal eye decoding, leading to degraded performance.

### BRIEF DESCRIPTION OF THE DRAWINGS

The following description includes discussion of figures having illustrations given by way of example of an implementation. The drawings should be understood by way of example, and not by way of limitation. As used herein, references to one or more examples are to be understood as describing a particular feature, structure, or characteristic included in at least one implementation of the invention. Phrases such as “in one example” or “in an alternative example” appearing herein provide examples of implementations of the invention, and do not necessarily all refer to the same implementation. However, they are also not necessarily mutually exclusive.

FIG. 1 is a block diagram of an example of a system that trains upper and lower data eyes separately.

FIG. 2A is a representation of an example of a data eye for PAM3 signaling.

FIG. 2B is a representation of an example of a data eye for PAM4 signaling.

FIG. 3 is a block diagram of an example of a system with power distribution networks having different DC offsets.

FIG. 4A is an example of a table of voltage level comparisons.

FIG. 4B is an example of a table of Vref coding.

FIG. 4C is an example of a table of voltage levels.

FIG. 5 is an example of a timing diagram for training a memory PHY with a common data signal line.

FIG. 6 is an example of a timing diagram for training a memory PHY with an additional data signal line.

FIG. 7 is an example of a timing diagram for training a memory PHY with a loopback signal line.

FIG. 8 is a block diagram of an example of a system with upper and lower latches.

FIG. 9 is an example of a PAM3 signal with upper and lower latches separately configured for Vref.

FIG. 10 is an example of a PAM3 decoding table.

FIG. 11 is a diagrammatic example of a Vref adaptation for a signal.

FIG. 12 is a flow diagram of an example of a process for training a host PHY.

FIG. 13 is a flow diagram of an example of a process for training a memory PHY.

FIG. 14 is a block diagram of an example of a memory subsystem in which training upper and lower data eyes separately can be implemented.

FIG. 15 is a block diagram of an example of a computing system in which training upper and lower data eyes separately can be implemented.

FIG. 16 is a block diagram of an example of a mobile device in which training upper and lower data eyes separately can be implemented.

FIG. 17 is a block diagram of an example of a multi-node network in which training upper and lower data eyes separately can be implemented.

Descriptions of certain details and implementations follow, including non-limiting descriptions of the figures, which may depict some or all examples, and well as other potential implementations.

### DETAILED DESCRIPTION OF THE INVENTION

As described herein, a system trains a physical interface (PHY) for inter-device communication with a pulse-amplitude modulation (PAM) signal having at least two data eyes. The system can train each eye separately to find the optimal reference voltage (Vref) that will place the Vref at the vertical center of the eye. The optimal Vref for each data eye can create an offset relative to the corresponding eye's common mode voltage. The PHY training includes adjusting the Vref for the different data eyes separately. Thus, the system can train one eye at a time and then send training signals to ensure that the separate Vrefs work for signaling with the multiple data eyes together. The training computes codes to center reference voltages on respective data eyes.

One specific application of PAM signaling is the transition of graphics memory (e.g., graphics double data rate (GDDR) memory) away from non-return to zero (NRZ) signaling to PAM3 signaling, where PAM3 refers to pulse amplitude modulation with three (3) signal voltage levels and two (2) data eyes. Reference throughout is primarily to PAM3 signaling, but it will be understood that PAM4 (pulse amplitude modulation with four (4) signal voltage levels and three (3) data eyes)) signaling can apply the same techniques to separately train the 3 data eyes.

In a practical system, the data eyes tend to be unsymmetrical. Training the data eyes independently can enable better alignment of the voltage reference (Vref) signal with the vertical center of the data eye. Centering the Vref signal on the data eye improves the ability of the system to correctly decode the PAM signaling. Improvement of the data eye improves the bit error rate (BER) performance of the signal decoder.

When the transmitting device and the receiving device are connected to the same low voltage reference or circuit ground, differences in the power distribution network (PDN) can result in a common mode voltage differential across the communication channel (e.g., signal line). The PDN refers to the power path that provides the high voltage and low voltage references from the and need to be trained independently for optimal. The common mode voltage refers to the DC offset between the PDNs of the different devices (e.g., a dynamic random access memory (DRAM) PDN and a host PDN), which leads to a non-optimal data eye, which in turn leads to degraded signal decoding.

With a bidirectional data channel, two connected devices will take turns being the transmitter and the receiver, depending on which direction the data is being transmitted. In one example, each device can separately train the multiple data eyes for its particular PHY, setting Vref levels that will enable the best performance. In a system such as a memory subsystem, there are systems in which the host (e.g., the memory controller) has a control circuit to set the parameters of the host PHY, and the memory device (e.g., a DRAM device) does not have a control circuit to set its PHY parameters for PAM decoding. In one example, both the host and the memory device have control circuits to set their respective PAM decoders. In one example, the memory device can provide an error signal back to the host, and the host control circuit can compute PHY settings for the memory device.

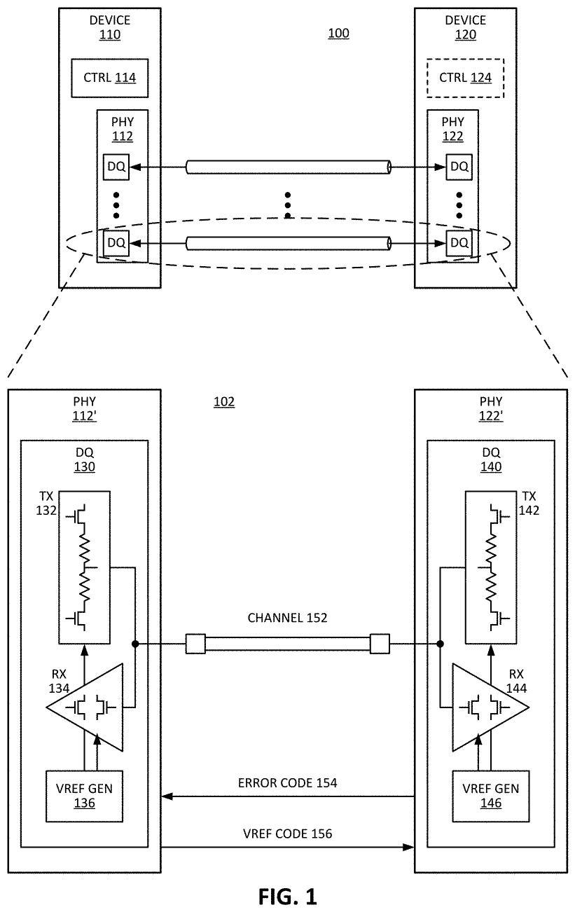

FIG. 1 is a block diagram of an example of a system that trains upper and lower data eyes separately. System 100 includes two devices coupled over a communication channel. In one example, system 100 is an example of a memory subsystem, with device 110 as the host/memory controller, and device 120 as the memory/DRAM device.

Device 110 includes physical interface (PHY) 112 and device 120 includes physical interface (PHY) 122. PHY 112 and PHY 122 include data (DQ) signal line interfaces, coupled together through signal lines. The number of DQ interfaces depends on the data bus for the system used, such as 8 signal lines, 10 signal lines, or some other number of data signal lines in the data bus.

System 102 represents details of the dashed portion of system 100. System 102 includes PHY 112′, which is an example of PHY 112 in a memory subsystem host. System 102 includes PHY 122′, which is an example of PHY 122 in a memory subsystem memory device.

PHY 112′ illustrates details for one DQ interface, represented as DQ 130. DQ 130 includes transceiver circuitry to couple to channel 152, which represents a data signal line that carries the PAM signal between the devices. The transceiver circuitry includes transmit circuit TX 132 and receive circuit 134 coupled to channel 152. Similarly, PHY 122′ illustrates details for a corresponding DQ interface, represented as DQ 140. DQ 140 includes transceiver circuitry to couple to channel 152, which represents a data signal line that carries the PAM signal between the devices. The transceiver circuitry includes transmit circuit TX 142 and receive circuit 144 coupled to channel 152. TX 132 and TX 142 drive signals onto channel 152. RX 134 and RX 144 receive signals driven by the complementary TX circuit.

As illustrated, DQ 130 includes reference voltage (Vref) generator (GEN) 136 and DQ 140 includes reference voltage (Vref) generator (GEN) 146. Vref GEN 136 generates reference voltages for TX 132 and RX 134 to set operation for the multiple data eyes of PAM signaling on channel 152. Similarly, Vref GEN 146 generates reference voltages for TX 132 and RX 134 to set operation for the multiple data eyes of PAM signaling on channel 152.

Device 110 includes control circuit (CTRL) 114 to compute and set the Vref levels for Vref GEN 136 to generate for DQ 130. In one example, device 120 includes control circuit (CTRL) 124 to compute and set the Vref levels for Vref GEN 146 to generate for DQ 140. CTRL 124 can be an optional component, where device 120 may not include a control circuit to compute the Vref levels. In such an implementation, CTRL 114 can compute the Vref levels for Vref GEN 146 to apply to DQ 140. The computation of the Vref levels can be or include computation of DC offset values relative to the ideal voltage level to adjust the Vref level relative to the common mode voltage.

In one example, CTRL 112 generates a known data pattern to send over channel 152 to device 120. In one example, device 120 returns the data to device 110, and CTRL 112 can determine what errors may have occurred, and send another known data pattern over channel 152 to repeat the testing. Thus, CTRL 112 can iteratively provide the known data pattern, iteratively compute errors in the return data and adjust the Vref DC voltage levels for the data eyes separately. In one example, for each iteration, CTRL 112 changes a Vref code for Vref GEN 136 until a BER is within an accepted range.

To train the Vref levels for Vref GEN 146, CTRL 114 can send the known data pattern over the data channel, and receive error code 154 from PHY 122′ of device 120. Error code 154 can indicate errors in the received data, assuming device 120 also knows the known data pattern and can check the received data against the known data pattern. In response to error code 154, CTRL 114 can compute the offsets for Vref GEN 146.

In one example, error code 154 represents a code determined by device 120 for the known data pattern received on a particular training iteration. In one example, instead of generating a code based on data received, the error code can simply be the data pattern as received at DQ 140. Such data can be referred to as an error code in that the data will be what is received and is not necessarily identical to what is sent.

In one example, PHY 122′ sends error code 154 over a different channel than the one being trained. Thus, for example, when training channel 152 between DQ 130 and DQ 140, PHY 122′ can send error code 154 across a different DQ channel between other DQ interfaces (not specifically shown in system 102). In one example, PHY 122′ can simply return the received data over the different data channel. In one example, PHY 122′ can return the received data over a loopback channel. A loopback channel refers to a signal line associated with a DQ channel (and typically associated with multiple DQ channel, multiplexed to receive the loopback data from any one of multiple DQ interfaces). The loopback channel passes data back to the sender without storing the data in a memory array.

In one example, device 120 includes CTRL 124. In an example where device 120 includes CTRL 124, CTRL 124 can detect the received data, compute the Vref levels, and set the offsets for Vref GEN 146. Thus, CTRL 124 represents optional intelligence in device 120 to compute Vref offset codes for its PHY.

In one example, CTRL 114 shmoos the voltage levels for the Vref for the different data eyes, depending on which data eye is being trained for the PHY of device 110. To shmoo the data eye refers to iteratively adjusting a parameter (e.g., the Vref levels), test the performance of the data eye with the new parameter setting, and repeat the iteration if the performance is not within accepted ranges. In one example, CTRL 124 can shmoo the DC offsets for the Vref for the different data eyes, depending on which data eye is being trained for the PHY of device 120. In one example, where data 120 does not include CTRL 124, CTRL 114 can shmoo the voltage levels for the Vref for the different data eyes for the PHY of device 120.

By separately training the different data eyes, system 100 can have higher eye margins (e.g., eye width (EW) margin and eye height (EH) margin) than a system that trains the data eyes together. Additionally, training the data eyes separately leads to improved precision in the Vref for the different data eyes, which reduces the burden on the power delivery to be matched across the different devices. Thus, even with differences in skew, power consumption, and load line differences, the Vref can be matched on each side of the DQ channel for the separate data eyes. Training the data eyes can include computing training codes for the Vref levels.

It will be understood that separately training the different PHYs for the multiple data eyes of the PAM signaling, the Vref levels will not necessarily be the same across system 100 or system 102. Consider an example where device 110 represents a memory controller and device 120 represents a GDDR memory device, and the devices communicate with PAM3 signaling. PAM3 signaling has an upper data eye and a lower data eye. The DC offset for Vref for the upper data eye can be different for device 110 (or more precisely, for PHY 112 of device 110) than for device 120 (again, to be more precise, for PHY 122 of device 120).

Similarly, the DC offsets for Vref for the lower data eye can be different for device 120 and device 110. The differences in Vref can be different in magnitude (e.g., the voltage level) as well as the differential between the upper and lower eyes (e.g., the relative difference in upper eye offset and lower eye offset). The differences in Vref can be different for either the upper eye, or the lower eye, or for both the upper eye and the lower eye, for the difference between the upper eye and the lower eye, or a combination of all of these differences.

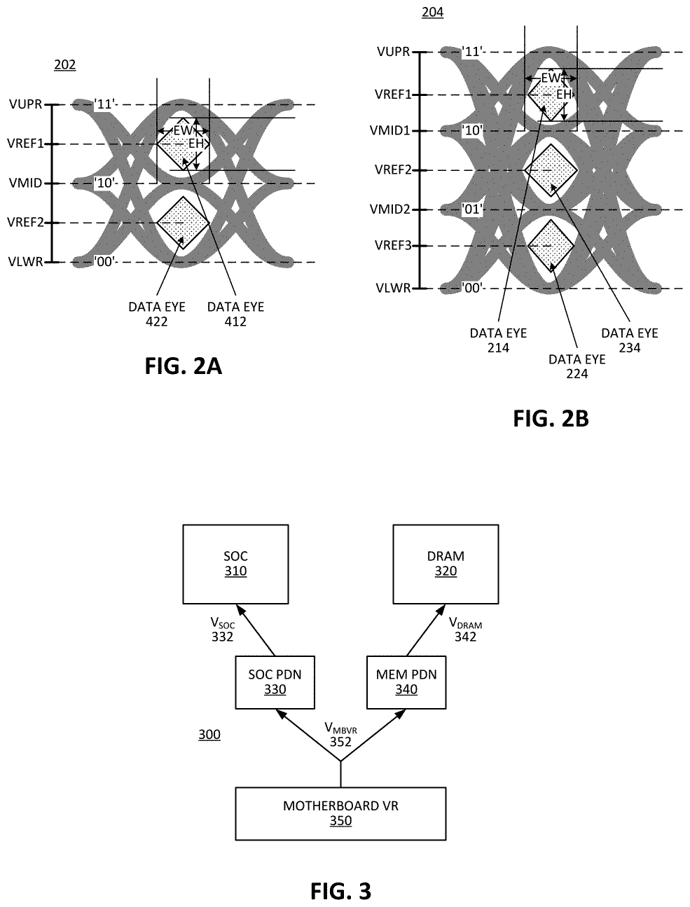

FIG. 2A is a representation of an example of a data eye for PAM3 signaling. Diagram 202 represents a data eye diagram showing the two data eyes at an IO interface of a device that exchanges data over a bidirectional bus with PAM3 signaling. The signaling is represented with thick gray lines, representing a signal average for multiple iterations of signaling at the different levels.

Diagram 202 has the upper voltage level (VUPR), a mid level voltage (VMID), and a lower voltage level (VLWR). For PAM3 signaling, VUPR can be decoded as a ‘11’, VMID can be decoded as a ‘10’, and VLWR can be decoded as a ‘00’. Transition from ‘11’ to ‘10’, transition from ‘10’ to ‘11’, and transition from ‘00’ to ‘11’ all combine to define data eye 212. Transition from ‘11’ to ‘00’, transition from ‘10’ to ‘00’, and transition from ‘00’ to ‘10’ all combine to define data eye 222.

Data eye 212 and data eye 222 are represented by the diamonds in between the signal representations. The diamonds illustrate an eye width (EW) and an eye height (EH). Outside the EW and the EH, the signal has margins, which are ranges between the data eye and the signal average.

Diagram 202 illustrates VREF1 as a Vref for data eye 212, the upper data eye, and VREF2 as the Vref for data eye 222, the lower data eye. As described herein, the system can train the voltage level of VREF1 and VREF2 separately to independently set the voltage levels that result in the best signaling performance. The training determines an optimal sampling point and the optimal reference voltage for the sampling point. Reference to “optimal” is understood to mean a relative best level for a specific system under the test conditions and does not necessarily mean an absolute optimum. The trained Vref provides the best margins on EH and EW that can be achieved by the system.

FIG. 2B is a representation of an example of a data eye for PAM4 signaling. Diagram 204 represents a data eye diagram showing the three data eyes at an IO interface of a device that exchanges data over a bidirectional bus with PAM4 signaling. The signaling is represented with thick gray lines, representing a signal average for multiple iterations of signaling at the different levels.

Diagram 204 has the upper voltage level (VUPR), a first mid level voltage (VMID1), a second mid level voltage (VMID2), and a lower voltage level (VLWR). For PAM4 signaling, VUPR can be decoded as a ‘11’, VMID1 can be decoded as a ‘10’, VMID2 can be decoded as ‘01’, and VLWR can be decoded as a ‘00’. Transition from ‘11’ to ‘10’, transition from ‘10’ to ‘11’, transition from ‘01’ to ‘11’, and transition from ‘00’ to ‘11’ all combine to define data eye 214. Transition from ‘11’ to ‘01’, transition from ‘10’ to ‘01’, transition from ‘01’ to ‘10’, and transition from ‘00’ to ‘10’ all combine to define data eye 224. Transition from ‘11’ to ‘00’, transition from ‘10’ to ‘00’, transition from ‘01’ to ‘00’, and transition from ‘00’ to ‘01’ all combine to define data eye 234.

Data eye 214, data eye 224, and data eye 234 are represented by the diamonds in between the signal representations. The diamonds illustrate an eye width (EW) and an eye height (EH). Outside the EW and the EH, the signal has margins, which are ranges between the data eye and the signal average. It will be understood that the different data eyes do not necessarily have the same EW or the same EH, although they may.

Diagram 204 illustrates VREF1 as a Vref for data eye 214, the upper data eye, VREF2 as the Vref for data eye 224, the middle data eye, and VREF3 as the Vref for data eye 234, the lower data eye. As described herein, the system can train the voltage level of VREF1, VREF2, and VREF3 separately to independently set the voltage levels that result in the best signaling performance. The training determines an optimal sampling point and the optimal reference voltage for the sampling point. The trained Vref provides the best margins on EH and EW that can be achieved by the system.

FIG. 3 is a block diagram of an example of a system with power distribution networks having different DC offsets. System 300 represents a system in accordance with an example of system 100. System 300 focuses on the power distribution and does not specifically illustrate the data channel or the components related to the computation of Vref offsets.

System 300 includes system on a chip (SOC) 310, which represents a host computing component. More specifically, SOC 310 includes a processor, such as a graphics processing unit (GPU), a central processing unit (CPU), or some other processor. SOC 310 includes a memory controller to manage access to DRAM 320. In one example, SOC 310 includes a multicore processor. In one example, SOC 310 includes chiplets or tiles with processor devices and interconnect components.

DRAM 320 represents volatile memory resources in system 300. DRAM 320 can be or include graphics memory or system memory. DRAM 320 represents memory resources to store data and code for computation operations by the processor of SOC 310. DRAM 320 can represent a memory module (e.g., a dual inline memory module (DIMM)) with multiple discrete memory devices.

Motherboard voltage regulator (VR) 350 represents a common voltage regulator for SOC 310 and DRAM 320. Although SOC 310 and DRAM 320 share the voltage regulator, they have independent power delivery networks (PDNs). SOC PDN 330 represents the power delivery network to power SOC 310. Memory (MEM) PDN 340 represents the power delivery network to power DRAM 320.

Motherboard VR 350 provides VMBVR 352 to SOC PDN 330 and to MEM PDN 340. The different power delivery networks can have different DC offsets. The PDN paths are unmatched paths. Thus, VSOC 332 provided by SOC PDN 330 to SOC 310 and VDRAM 342 provided by MEM PDN 340 to DRAM 320 can be different voltage levels.

While not specifically illustrated, system 300 can include a comparator to compare the common mode voltage for a data channel. The system can include a comparator per data channel. The comparator(s) can determine the common mode DC voltage differential across a signaling channel. DC voltage difference between the transmitter and receiver would reduce the margin of the memory receiver without training the memory receiver Vref. In one example, system 300 detects the voltage difference between the TX and the RX and applies the delta/difference in the Vref value.

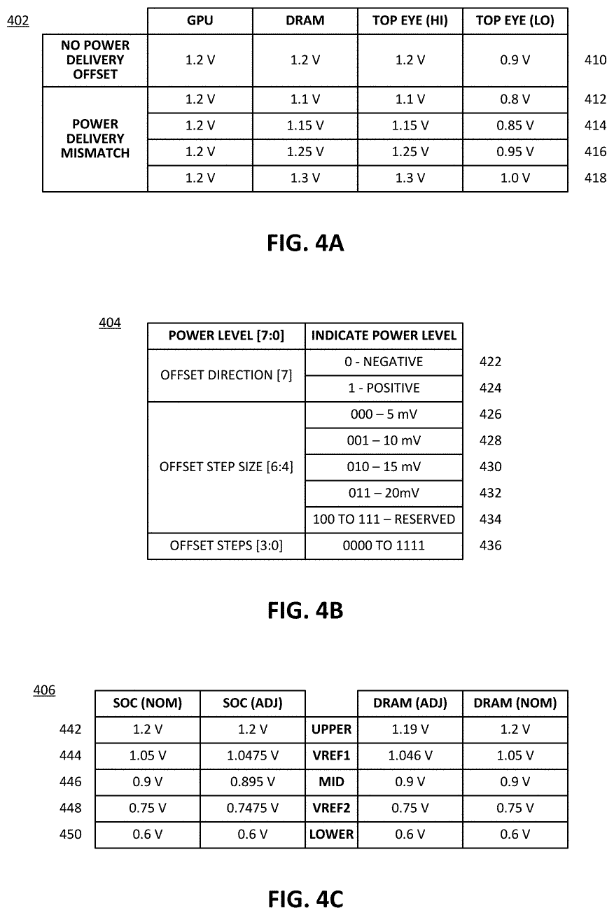

FIG. 4A is an example of a table of voltage level comparisons. Consider a system where a single voltage regulator (VR) drives power to both a GPU and a DRAM. In a practical application, there is a difference in the voltage level between the GPU die and the DRAM die(s) due to package, current consumption, on die differences to the circuitry, or other differences, cause a transmitter to drive signals at voltage levels different from the ideal. Not knowing the specific level at the GPU receiver would cause the receiver to set the Vref at the wrong start point.

A system as described can detect the power difference between the communicating devices and adjust the Vref. In one example, the devices adjust and set the Vref levels through a handshake mechanism to communicate the direction and magnitude of the voltage differences.

Table 402 illustrates possible voltage levels that could occur. Row 410 illustrates the ideal levels, where there is no power delivery offset. Such levels can be 1.2 V at the GPU, 1.2 V at the DRAM, 1.2 V for the high voltage of the top eye, and 0.9 V for the low voltage of the top eye. For simplicity, the voltage levels of the lower eye are not illustrated.

The other rows illustrate possible DC voltage offsets when there is a power delivery mismatch. Row 412 illustrates 1.2 V at the GPU, 1.1 V at the DRAM, 1.1 V for the high level of the top eye, and 0.8 V of the low level of the top eye. Row 414 illustrates 1.2 Vat the GPU, 1.15 V at the DRAM, 1.15 V for the high level of the top eye, and 0.85 V of the low level of the top eye. Row 416 illustrates 1.2 V at the GPU, 1.25 V at the DRAM, 1.25 V for the high level of the top eye, and 0.95 V of the low level of the top eye. Row 418 illustrates 1.2 V at the GPU, 1.3 V at the DRAM, 1.3 V for the high level of the top eye, and 1.0 V of the low level of the top eye.

FIG. 4B is an example of a table of Vref coding. Table 404 provides an example of a Vref/VREF training code in accordance with any example of computing training codes to apply a DC offset to set the Vref. In the example of table 404, there are eight bits, Power Level [7:0]. An example of the power level bit decoding is indicated in the other column.

Bit [7] can indicate an offset direction. Row 422 indicates that when bit [7] is ‘0’, the offset direction is negative, and row 424 indicates that when bit [7] is ‘1’, the offset direction is positive.

Bits [6:4] can indicate an offset step size, row 426 indicates that when bits [6:4] are ‘000’, the offset can be 5 mV steps. Row 428 indicates that when bits [6:4] are ‘001’, the offset can be 10 mV steps. Row 430 indicates that when bits [6:4] are ‘010’, the offset can be 15 mV steps. Row 432 indicates that when bits [6:4] are ‘011’, the offset can be 20 mV steps. Row 434 indicates that either bit [6] or bit [4] is reserved. The additional bit can be unused, or can be combined with the offset steps. Alternatively, the step sizes can be smaller, and more step sizes can be defined.

Bits [3:0] can indicate the number of steps to make for VREF adjustment. Row 436 indicates that there can be anywhere from zero (‘0000’) to fifteen (‘1111’) steps. The combination of the offset step size and the offset steps indicates the magnitude of the offset voltage.

In one example, the Vref offset is an initial supply rail offset, which is information communicated between the different devices (e.g., between the DRAM and the GPU). In one example, the devices engage in a digital handshake, and part of the handshake can be to communicate the analog voltage difference from the ideal. The digital handshake can be programmed based on the capability of the participating devices (e.g., different DRAM vendors may support different capabilities).

FIG. 4C is an example of a table of voltage levels. Table 406 provides an example of the SOC nominal (SOC (NOM)) voltage levels, which are the voltage levels of the design, the SOC adjusted voltage levels (SOC (ADJ)), which are the trained levels based on measuring the real power delivery, the DRAM nominal (DRAM (NOM)) voltage levels, and the DRAM adjusted (DRAM (ADJ)) voltage levels. Row 442 represents the upper voltage rail/voltage level, row 450 represents the lower voltage rail/voltage level, and row 446 represents the mid-level voltage. Row 444 represents the voltage level VREF1, which is the voltage reference for the upper data eye, and row 448 represents the voltage level VREF2, which is the voltage reference for the lower data eye.

The nominal voltage levels for both the SOC and the DRAM are 1.2 V for the upper level, 0.6 V for the lower level, 0.9 V for the mid level, 1.05 V for VREF1, and 0.75 V for VREF2. The upper level refers to a high voltage for PAM signaling, the mid level refers to the mid level voltage for PAM signaling, and the lower level refers to the low voltage level for the PAM signaling.

In the example of table 406, the DRAM upper voltage level is 1.19 V, which is lower than the nominal 1.2 V. To adjust for the lower high voltage level at the RX input/output (IO), a system such as system 300, in accordance with adjustments such as illustrated in table 404, adjusts the upper Vref (VREF1) by 5 mV on the memory (DRAM) side, and the upper Vref (VREF1) and the lower Vref (VREF2) by 5 mV on the host (SOC) side. Thus, the SOC voltage levels for the upper level, VREF1, mid level, VREF2, and lower level, respectively, are 1.2 V, 1.0475 V, 0.895 V, 0.7475 V, and 0.6 V. The DRAM voltage levels for the upper level, VREF1, mid level, VREF2, and lower level, respectively, are 1.19 V, 1.045 V, 0.9 V, 0.75 V, and 0.6 V.

The training of the Vref levels can include computing a Vref level per data eye (e.g., for both data eyes of a PAM3 system, or for all three data eyes of a PAM4 system), one data eye at a time. The system trains one data eye, then the second data eye, and optionally the third data eye. Training the eyes separately can involve the use of a known data pattern (e.g., a specific sequence of O's and 1's) that applies only to one data eye.

The system can then train both eyes together by applying a data pattern that applies to both data eyes. For a system that has more than two data eye, the system can train all data eyes together by applying data patterns that apply to combinations of two data eyes or to all three data eyes at the same time. The training can be referred to as a loop, as the system iteratively repeats the training of the data eye. The training with the loops can converge to the Vref levels selected for the data eyes, such as the levels indicated in table 406.

The voltage levels detected can be detected in one of multiple ways. In one example, the system measures the voltage levels through training. The training determines the differences in voltage level, through the system apply a shmoo of the Vref training codes to determine a code that provides a best BER. In one example, the system can be measured through a testing apparatus or a quality assurance system to pre-measure the offsets between the paths after building of the system. Based on the pre-measured offsets, the testing can compute training codes for the measured levels. The measurement can determine the offsets between the paths, giving a starting point for training codes. In one example, the system can use pre-measurement and then use training to fine-tune the pre-measurement levels.

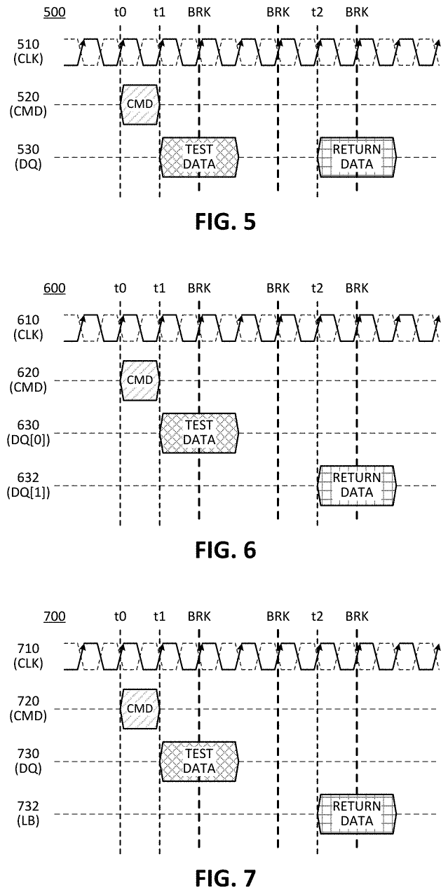

FIG. 5 is an example of a timing diagram for training a memory PHY with a common data signal line. Diagram 500 represents a timing diagram of the timing for training a PHY using a data signal line being trained. Signal 510 represents a clock (CLK) signal on one or more signal lines, which represents the clock signal that controls the timing of command signals for signal 520. Signal 520 represents a command (CMD) signal to identify the command associated with data to be sent. Signal 530 represents the data (DQ) signal.

At time t0, the training device sends a command (CMD) on signal 520. At time t1, the training device sends a sequence of test data on signal 530. The data can be a sequence of data longer than what is illustrated, as shown by the time break, BRK. After some time, at time t2, the receiving device can send the return data.

Based on the return data, the training device can compute Vref offsets for PHYs of the connected devices. In one example, the receiving device performs all training of its PHY, and the return data may be unnecessary. After the return data, such as an error signal reply, the training device can iteratively send the test data, which is a known data pattern. Based on the error signals, the training device can compute the Vref codes of the PHY of the receiving device.

FIG. 6 is an example of a timing diagram for training a memory PHY with an additional data signal line. Diagram 600 represents a timing diagram of the timing for training a PHY using a data signal line being trained. Signal 610 represents a clock (CLK) signal on one or more signal lines, which represents the clock signal that controls the timing of command signals for signal 620. Signal 620 represents a command (CMD) signal to identify the command associated with data to be sent. Signal 630 represents the data signal of the data signal line being trained, represented as DQ[0] in diagram 600. Signal 632 represents the data signal of the data signal line used for providing return data/error signals, represented as DQ[1] in diagram 600.

At time t0, the training device sends a command (CMD) on signal 620. At time t1, the training device sends a sequence of test data on signal 630. The data can be a sequence of data longer than what is illustrated, as shown by the time break, BRK. After some time, at time t2, the receiving device can send the return data on signal 632.

Based on the return data, the training device can compute Vref offsets for PHYs of the connected devices. In one example, the receiving device performs all training of its PHY, and the return data may be unnecessary. After the return data, such as an error signal reply, the training device can iteratively send the test data, which is a known data pattern. Based on the error signals, the training device can compute the Vref codes of the PHY of the receiving device.

FIG. 7 is an example of a timing diagram for training a memory PHY with a loopback signal line. Diagram 700 represents a timing diagram of the timing for training a PHY using a data signal line being trained. Signal 710 represents a clock (CLK) signal on one or more signal lines, which represents the clock signal that controls the timing of command signals for signal 720. Signal 720 represents a command (CMD) signal to identify the command associated with data to be sent. Signal 730 represents the data signal of the data signal line (DQ) being trained. Signal 732 represents the data signal of a loopback signal line (LB) used for providing return data/error signals.

At time t0, the training device sends a command (CMD) on signal 720. At time t1, the training device sends a sequence of test data on signal 730. The data can be a sequence of data longer than what is illustrated, as shown by the time break, BRK. After some time, at time t2, the receiving device can send the return data on signal 732.

Based on the return data, the training device can compute Vref offsets for PHYs of the connected devices. In one example, the receiving device performs all training of its PHY, and the return data may be unnecessary. After the return data, such as an error signal reply, the training device can iteratively send the test data, which is a known data pattern. Based on the error signals, the training device can compute the Vref codes of the PHY of the receiving device.

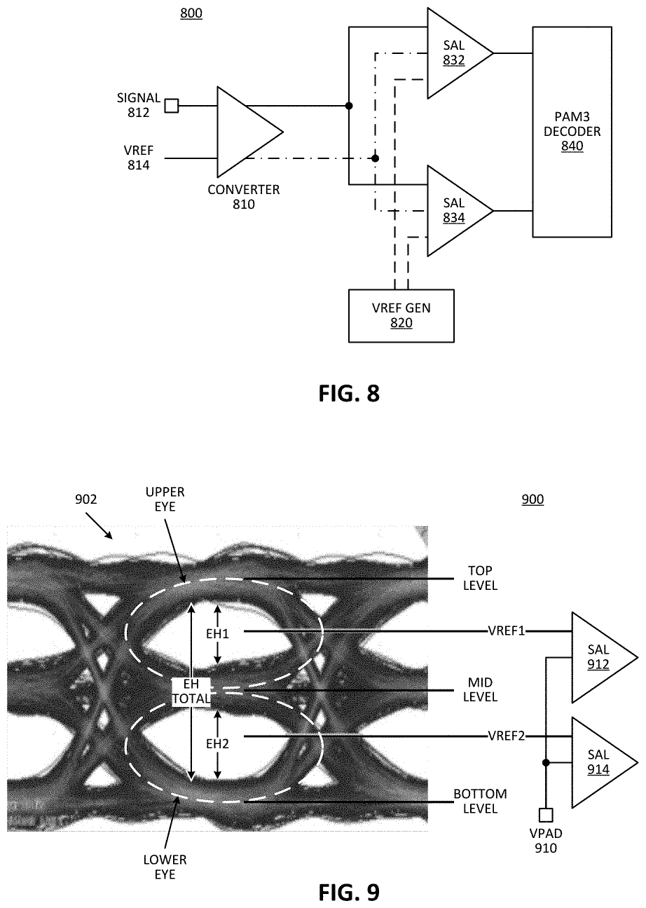

FIG. 8 is a block diagram of an example of a system with upper and lower latches. System 800 illustrates a PAM3 receiver architecture in accordance with an example of system 100 or an example of system 300. In one example, the receiver architecture is for a memory device.

System 800 includes converter 810, which represents a single to differential converter, to convert signal 812 into a differential signal. VREF 814 represents a DC voltage reference used to decode signal 812. Converter 810 can represent a frontend receiver gain stage, which is followed by a SAL stage to compare the incoming signal with an on-die generated common mode signal, which is the VREF signal.

PAM3 decoder 840 represents a decoder to determine a signal value associated with the voltage level of signal 812. In one example, PAM3 decoder 840 decodes the signal based on determining the signal level of the incoming signal, based on the reference to the data eyes. In one example, system 800 includes strong arm latch (SAL) 832 and SAL 834. A strong arm latch is a type of comparator to generate a difference based on differential signals.

SAL 832 can compare the primary signal from converter 810 against the complementary signal from converter 810 against a VREF signal from VREF generator (GEN) 820. The first VREF signal is a signal for the upper eye. SAL 834 can compare the primary signal from converter 810 against the complementary signal from converter 810 against another VREF signal from VREF GEN 820. The other VREF signal is a signal for the lower eye. Based on the comparison of the signals, PAM3 decoder 840 can generate a ratio level mismatch (RLM).

FIG. 9 is an example of a PAM3 signal with upper and lower latches separately configured for Vref. System 900 is a system in accordance with an example of system 800, where system 900 illustrates the data eyes with the strong arm latches.

Diagram 902 illustrates an example of PAM3 signaling with an upper eye and a lower eye. The upper eye has an eye height of EH1 and the lower eye has an eye height of EH2. The system can compute the RLM in accordance with a formula: RLM=(min(EH1,EH2))/(EH_Total/2).

System 900 illustrates a top level voltage, a mid level voltage, and a bottom level voltage, representing the three voltage levels for the PAM3 signaling. The other lines illustrate the VREF levels that are received into the strong arm latches. More specifically, the top VREF signal is associated with the upper eye, and acts as a reference for SAL 912. The bottom VREF signal is associated with the lower eye, and acts as a reference for SAL 914. VPAD 910 represents a pad voltage, which is the incoming signal on the channel. In accordance with what is described herein, system 900 can set the upper and lower reference voltages independently.

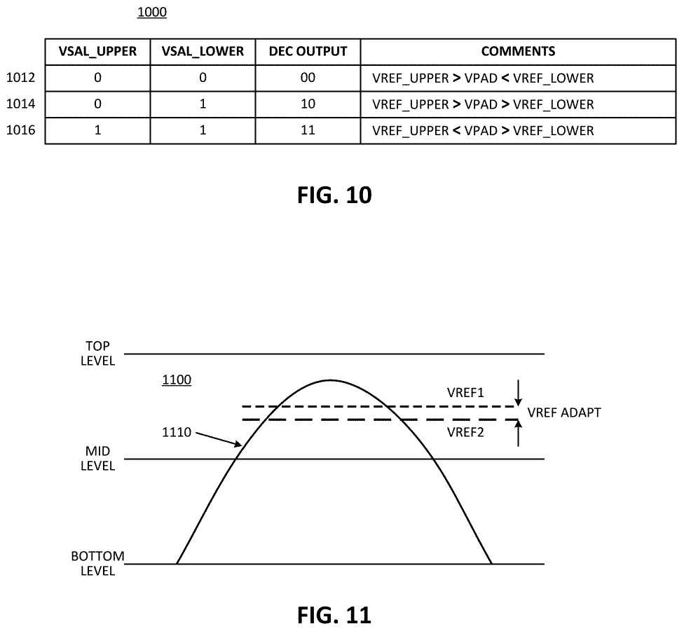

FIG. 10 is an example of a PAM3 decoding table. Table 1000 represents a table that can be used for PAM3 decoding in accordance with an example of system 100, system 300, or system 800. The table columns are the voltage indication of the upper SAL (VSAL_UPPER), the voltage indication of the lower SAL (VSAL_LOWER), the decoder (DEC) output, and comments to indicate how the decoded output is achieved.

Row 1012 illustrates a situation where VSAL_UPPER is ‘0’ and VSAL_LOWER is ‘0’, which decodes to ‘00’. Such an output is decoded when VREF_UPPER>VPAD, and VREF_LOWER>VPAD, which means the signal is below both data eyes.

Row 1014 illustrates a situation where VSAL_UPPER is ‘0’ and VSAL_LOWER is ‘1’, which decodes to ‘10’. Such an output is decoded when VREF_UPPER>VPAD, and VREF_LOWER<VPAD, which means the signal is above the bottom data eye and below the top data eye.

Row 1016 illustrates a situation where VSAL_UPPER is ‘1’ and VSAL_LOWER is ‘1’, which decodes to ‘11’. Such an output is decoded when VREF_UPPER<VPAD, and VREF_LOWER<VPAD, which means the signal is above both data eyes.

It can be observed that for such decoding to occur properly, the VREF_UPPER and VREF_LOWER need to be trained to be at the correct level for maximum margins. Especially when the upper eye and the lower eye are subject to non-uniformity, resulting in poor RLM, independently training VREF_UPPER and VREF_LOWER can improve the correct level for the reference voltages.

FIG. 11 is a diagrammatic example of a Vref adaptation for a signal. Diagram 1100 illustrates a portion of a signal that defines a data eye. More specifically, the signal is a transition from the bottom level voltage, to the top level voltage, back to the bottom level voltage. As illustrated the top of the curve of signal 1110 does not completely reach the top level voltage.

The ideal signal shape for signal 1110 would extend to the top level voltage. If signal 1110 is typical for the system, the eye between the top level and the mid level would not likely result in good decoding. VREF1 illustrates the ideal VREF that would be expected if signal 1110 reached all the way to the top level.

Assuming the lower curve at the top of signal 1110 defines a lower signaling for the top eye in the system represented by diagram 1100, the system can adjust the VREF to VREF2, which is lower than VREF1. VREF2 is placed approximately halfway between the top of signal 1110 and the mid level voltage, whereas VREF1 is placed approximately halfway between the top level voltage and the mid level voltage. The difference between VREF1 (the ideal VREF) and VREF2 (the adjusted VREF) is illustrated as VREF ADAPT, referring to the adaptation or the adjustment made to the DC offset for the top data eye.

VREF adaptation can address the inter symbol interference (ISI) non-linearity, which is channel dependent. Thus, the system can perform VREF adaptation per channel to set the eye reference voltages at the center of the data eyes, where the probability of detecting high and low are equal.

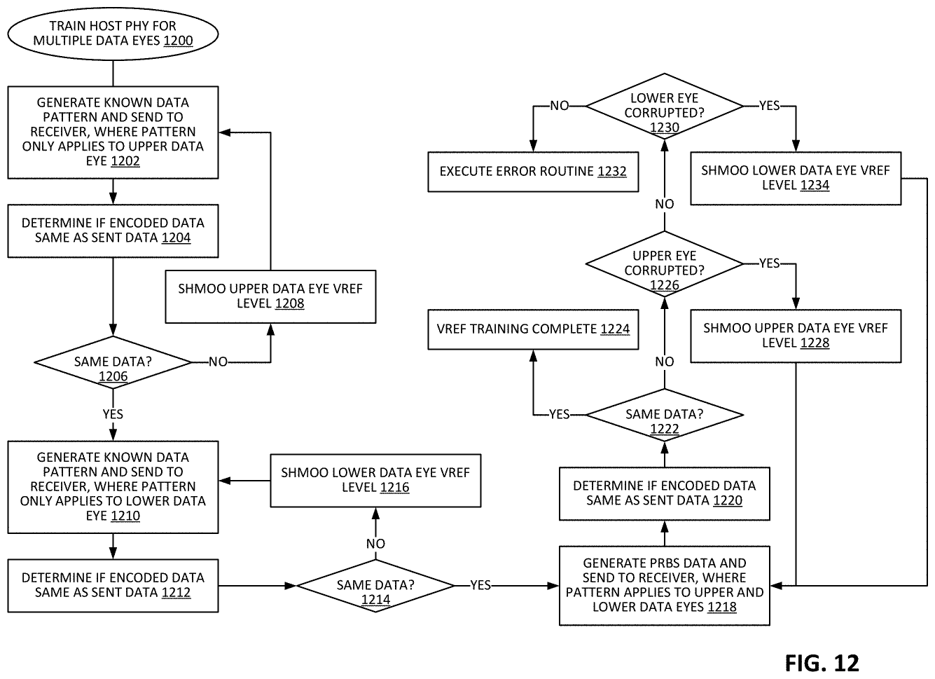

FIG. 12 is a flow diagram of an example of a process for training a host PHY. Process 1200 represents a process to train the host PHY for signaling with multiple data eyes.

The host can generate a known data pattern and send the data to the receiver, where the pattern only applies to the upper data eye, at 1202. The receiver can decode and send the data back, and the host can determine if the encoded data is the same as the sent data, at 1204. If the data is not the same, at 1206 NO branch, the host can shmoo the upper data eye VREF level, at 1208, and repeat generation and sending of the known data pattern for the upper eye.

If the data is the same, at 1206, YES branch, the host can generate a known data pattern and send the data to the receiver, where the pattern only applies to the lower data eye, at 1210. The receiver can decode and send the data back, and the host can determine if the encoded data is the same as the sent data, at 1212. If the data is not the same, at 1214 NO branch, the host can shmoo the lower data eye VREF level, at 1216, and repeat generation and sending of the known data pattern for the lower eye.

If the data is the same, at 1214, YES branch, the host can generate a pseudorandom binary sequence (PRBS) signal and send the data to the receiver, where the pattern applies to both the upper data eye and the lower data eye, 1218. The receiver can decode and send the data back, and the host can determine if the encoded data is the same as the sent data, at 1220. If the data is the same, at 1222 YES branch, the VREF training is complete, at 1224.

If the data is not the same, at 1222 NO branch, the host can determine if the data differences indicate that the upper data eye is corrupted or the lower data eye is corrupted. If the upper data eye is corrupted, at 1226 YES branch, the host can shmoo the upper data eye VREF level, at 1228, and repeat generation and sending of the PRBS. If the upper data eye is not corrupted, at 1226 NO branch, the lower data eye is corrupted.

If there is an error that the system cannot determine whether the upper data eye or the lower data eye is corrupted, at 1230 NO branch, the host can execute an error routine to diagnose and correct the error, at 1232. If the lower eye is corrupted, at 1230 YES branch, the host can shmoo the upper data eye VREF level, at 1234, and repeat generation and sending of the PRBS.

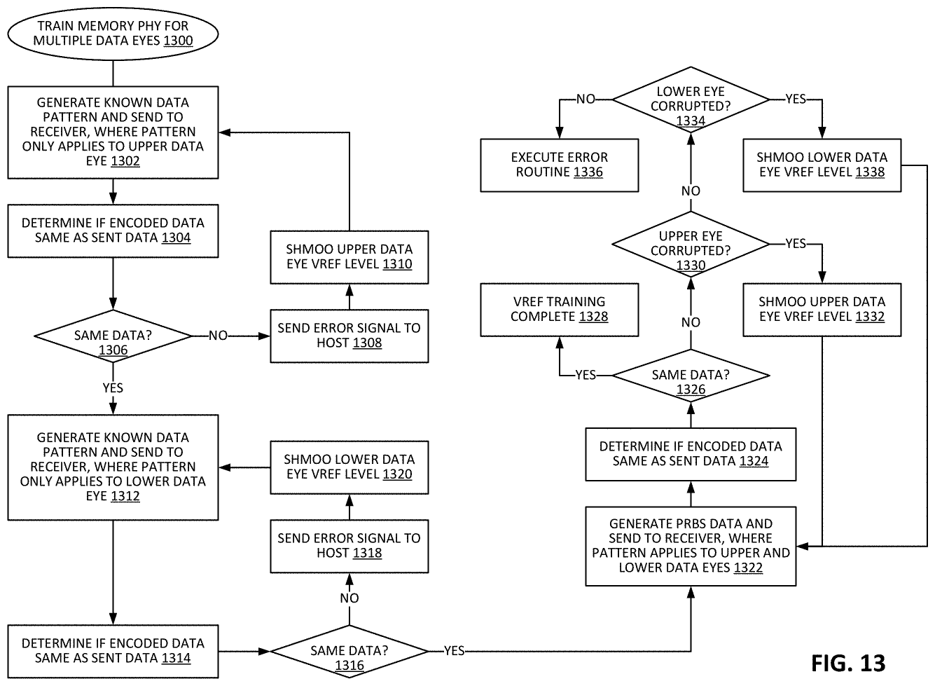

FIG. 13 is a flow diagram of an example of a process for training a memory PHY. Process 1300 represents a process to train the memory PHY for signaling with multiple data eyes. Process 1300 assumes host involvement in training the memory PHY. If the memory can train its own PHY, it can execute a process similar to what is described with reference to process 1200.

For host-assisted memory PHY training, the host can generate a known data pattern and send the data to the memory, where the pattern only applies to the upper data eye, at 1302. The memory can determine if the decoded data is the same as the sent data, at 1304. If the data is not the same, at 1306 NO branch, the memory can send an error signal to the host, at 1308, and based on the error signal, the host can shmoo the upper data eye VREF level, at 1310, and repeat generation and sending of the known data pattern for the upper eye.

If the data is the same, at 1306, YES branch, the host can generate a known data pattern and send the data to the memory, where the pattern only applies to the lower data eye, at 1312. The memory can determine if the decoded data is the same as the sent data, at 1314. If the data is not the same, at 1316 NO branch, the memory can send an error signal to the host, at 1318, and based on the error signal, the host can shmoo the lower data eye VREF level, at 1320, and repeat generation and sending of the known data pattern for the lower eye.

If the data is the same, at 1316, YES branch, the host can generate a pseudorandom binary sequence (PRBS) signal and send the data to the memory, where the pattern applies to both the upper data eye and the lower data eye, 1322. The memory can determine if the decoded data is the same as the sent data, at 1324. If the data is the same, at 1326 YES branch, the VREF training is complete, at 1328.

If the data is not the same, at 1326 NO branch, the host can determine if the data differences indicate that the upper data eye is corrupted or the lower data eye is corrupted. If the upper data eye is corrupted, at 1330 YES branch, the host can shmoo the upper data eye VREF level, at 1332, and repeat generation and sending of the PRBS. If the upper data eye is not corrupted, at 1330 NO branch, the lower data eye is corrupted.

If there is an error that the system cannot determine whether the upper data eye or the lower data eye is corrupted, at 1334 NO branch, the host can execute an error routine to diagnose and correct the error, at 1336. If the lower eye is corrupted, at 1334 YES branch, the host can shmoo the upper data eye VREF level, at 1338, and repeat generation and sending of the PRBS.

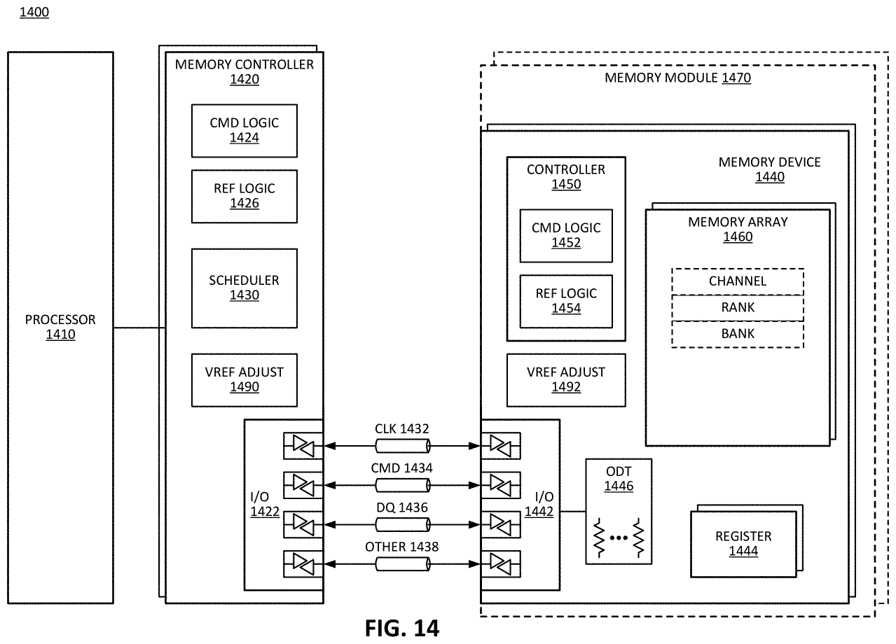

FIG. 14 is a block diagram of an example of a memory subsystem in which training upper and lower data eyes separately can be implemented. System 1400 includes a processor and elements of a memory subsystem in a computing device. System 1400 represents a system with a memory subsystem in accordance with an example of system 100 or an example of system 300.

In one example, system 1400 can separately train the different data eyes of a PAM signaling system. VREF adjust 1490 represents components in memory controller 1420 to enable the memory controller to generate training sequences and separately determine the Vref levels for the different data eyes. VREF adjust 1490 can train the PHY that is part of I/O 1422. VREF adjust 1492 represents components in memory device 1440 to enable the memory device to either send signals back, such as an error signal, or to separately decode and internally determine its Vref levels for the different data eyes. VREF adjust 1492 can train the PHY that is part of I/O 1442. VREF adjust 1490 and VREF adjust 1492 can set the VREF offsets in accordance with any example described.

Processor 1410 represents a processing unit of a computing platform that may execute an operating system (OS) and applications, which can collectively be referred to as the host or the user of the memory. The OS and applications execute operations that result in memory accesses. Processor 1410 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory accesses may also be initiated by devices such as a network controller or hard disk controller. Such devices can be integrated with the processor in some systems or attached to the processer via a bus (e.g., PCI express), or a combination. System 1400 can be implemented as an SOC (system on a chip), or be implemented with standalone components.

Reference to memory devices can apply to different memory types. Memory devices often refers to volatile memory technologies. Volatile memory is memory whose state (and therefore the data stored on it) is indeterminate if power is interrupted to the device. Nonvolatile memory refers to memory whose state is determinate even if power is interrupted to the device. Dynamic volatile memory requires refreshing the data stored in the device to maintain state. One example of dynamic volatile memory includes DRAM (dynamic random-access memory), or some variant such as synchronous DRAM (SDRAM). A memory subsystem as described herein may be compatible with a number of memory technologies, such as DDR4 (double data rate version 4, JESD79-4, originally published in September 2012 by JEDEC (Joint Electron Device Engineering Council, now the JEDEC Solid State Technology Association), LPDDR4 (low power DDR version 4, JESD209-4, originally published by JEDEC in August 2014), WIO2 (Wide I/O 2 (WideIO2), JESD229-2, originally published by JEDEC in August 2014), HBM (high bandwidth memory DRAM, JESD235A, originally published by JEDEC in November 2015), DDR5 (DDR version 14, originally published by JEDEC in July 2020), LPDDR5 (LPDDR version 14, JESD209-5, originally published by JEDEC in February 2019), HBM2 (HBM version 2, JESD235C, originally published by JEDEC in January 2020), HBM3 (HBM version 3, JESD238, originally published by JEDEC in January 2022), GDDR7 (graphics DDR version 7, in discussion), or others or combinations of memory technologies, and technologies based on derivatives or extensions of such specifications.

Memory controller 1420 represents one or more memory controller circuits or devices for system 1400. In one example, memory controller 1420 is on the same semiconductor substrate as processor 1410. Memory controller 1420 represents control logic that generates memory access commands in response to the execution of operations by processor 1410. Memory controller 1420 accesses one or more memory devices 1440. Memory devices 1440 can be DRAM devices in accordance with any referred to above. In one example, memory devices 1440 are organized and managed as different channels, where each channel couples to buses and signal lines that couple to multiple memory devices in parallel. Each channel is independently operable. Thus, each channel is independently accessed and controlled, and the timing, data transfer, command and address exchanges, and other operations are separate for each channel. Coupling can refer to an electrical coupling, communicative coupling, physical coupling, or a combination of these. Physical coupling can include direct contact. Electrical coupling includes an interface or interconnection that allows electrical flow between components, or allows signaling between components, or both. Communicative coupling includes connections, including wired or wireless, that enable components to exchange data.

In one example, settings for each channel are controlled by separate mode registers or other register settings. In one example, each memory controller 1420 manages a separate memory channel, although system 1400 can be configured to have multiple channels managed by a single controller, or to have multiple controllers on a single channel. In one example, memory controller 1420 is part of host processor 1410, such as logic implemented on the same die or implemented in the same package space as the processor.

Memory controller 1420 includes I/O interface logic 1422 to couple to a memory bus, such as a memory channel as referred to above. I/O interface logic 1422 (as well as I/O interface logic 1442 of memory device 1440) can include pins, pads, connectors, signal lines, traces, or wires, or other hardware to connect the devices, or a combination of these. I/O interface logic 1422 can include a hardware interface. As illustrated, I/O interface logic 1422 includes at least drivers/transceivers for signal lines. Commonly, wires within an integrated circuit interface couple with a pad, pin, or connector to interface signal lines or traces or other wires between devices. I/O interface logic 1422 can include drivers, receivers, transceivers, or termination, or other circuitry or combinations of circuitry to exchange signals on the signal lines between the devices. The exchange of signals includes at least one of transmit or receive. While shown as coupling I/O 1422 from memory controller 1420 to I/O 1442 of memory device 1440, it will be understood that in an implementation of system 1400 where groups of memory devices 1440 are accessed in parallel, multiple memory devices can include I/O interfaces to the same interface of memory controller 1420. In an implementation of system 1400 including one or more memory modules 1470, I/O 1442 can include interface hardware of the memory module in addition to interface hardware on the memory device itself. Other memory controllers 1420 will include separate interfaces to other memory devices 1440.

The bus between memory controller 1420 and memory devices 1440 can be implemented as multiple signal lines coupling memory controller 1420 to memory devices 1440. The bus may typically include at least clock (CLK) 1432, command/address (CMD) 1434, data (DQ) 1436, and zero or more other signal lines 1438. In one example, a bus or connection between memory controller 1420 and memory can be referred to as a memory bus. In one example, the memory bus is a multi-drop bus. The signal lines for CMD can be referred to as a “C/A bus” (or ADD/CMD bus, or some other designation indicating the transfer of commands (C or CMD) and address (A or ADD) information) and the signal lines for write and read DQ can be referred to as a “data bus.” In one example, independent channels have different clock signals, C/A buses, data buses, and other signal lines. Thus, system 1400 can be considered to have multiple “buses,” in the sense that an independent interface path can be considered a separate bus. It will be understood that in addition to the lines explicitly shown, a bus can include at least one of strobe signaling lines, alert lines, auxiliary lines, or other signal lines, or a combination. It will also be understood that serial bus technologies can be used for the connection between memory controller 1420 and memory devices 1440. An example of a serial bus technology is 8B10B encoding and transmission of high-speed data with embedded clock over a single differential pair of signals in each direction. In one example, CMD 1434 represents signal lines shared in parallel with multiple memory devices. In one example, multiple memory devices share encoding command signal lines of CMD 1434, and each has a separate chip select (CS_n) signal line to select individual memory devices.

It will be understood that in the example of system 1400, the bus between memory controller 1420 and memory devices 1440 includes a subsidiary command bus CMD 1434 and a subsidiary bus to carry the write and read data, DQ 1436. In one example, the data bus can include bidirectional lines for read data and for write/command data. In another example, the subsidiary bus DQ 1436 can include unidirectional write signal lines for write and data from the host to memory, and can include unidirectional lines for read data from the memory to the host. In accordance with the chosen memory technology and system design, other signals 1438 may accompany a bus or sub bus, such as strobe lines DQS. Based on design of system 1400, or implementation if a design supports multiple implementations, the data bus can have more or less bandwidth per memory device 1440. For example, the data bus can support memory devices that have either a x4 interface, a x8 interface, a x16 interface, or other interface. The convention “xW,” where W is an integer that refers to an interface size or width of the interface of memory device 1440, which represents a number of signal lines to exchange data with memory controller 1420. The interface size of the memory devices is a controlling factor on how many memory devices can be used concurrently per channel in system 1400 or coupled in parallel to the same signal lines. In one example, high bandwidth memory devices, wide interface devices, or stacked memory configurations, or combinations, can enable wider interfaces, such as a x128 interface, a x256 interface, a x512 interface, a x1024 interface, or other data bus interface width.

In one example, memory devices 1440 and memory controller 1420 exchange data over the data bus in a burst, or a sequence of consecutive data transfers. The burst corresponds to a number of transfer cycles, which is related to a bus frequency. In one example, the transfer cycle can be a whole clock cycle for transfers occurring on a same clock or strobe signal edge (e.g., on the rising edge). In one example, every clock cycle, referring to a cycle of the system clock, is separated into multiple unit intervals (UIs), where each UI is a transfer cycle. For example, double data rate transfers trigger on both edges of the clock signal (e.g., rising and falling). A burst can last for a configured number of UIs, which can be a configuration stored in a register, or triggered on the fly. For example, a sequence of eight consecutive transfer periods can be considered a burst length eight (BL8), and each memory device 1440 can transfer data on each UI. Thus, a x8 memory device operating on BL8 can transfer 64 bits of data (8 data signal lines times 8 data bits transferred per line over the burst). It will be understood that this simple example is merely an illustration and is not limiting.

Memory devices 1440 represent memory resources for system 1400. In one example, each memory device 1440 is a separate memory die. In one example, each memory device 1440 can interface with multiple (e.g., 2) channels per device or die. Each memory device 1440 includes I/O interface logic 1442, which has a bandwidth determined by the implementation of the device (e.g., x16 or x8 or some other interface bandwidth). I/O interface logic 1442 enables the memory devices to interface with memory controller 1420. I/O interface logic 1442 can include a hardware interface, and can be in accordance with I/O 1422 of memory controller, but at the memory device end. In one example, multiple memory devices 1440 are connected in parallel to the same command and data buses. In another example, multiple memory devices 1440 are connected in parallel to the same command bus, and are connected to different data buses. For example, system 1400 can be configured with multiple memory devices 1440 coupled in parallel, with each memory device responding to a command, and accessing memory resources 1460 internal to each. For a Write operation, an individual memory device 1440 can write a portion of the overall data word, and for a Read operation, an individual memory device 1440 can fetch a portion of the overall data word. The remaining bits of the word will be provided or received by other memory devices in parallel.

In one example, memory devices 1440 are disposed directly on a motherboard or host system platform (e.g., a PCB (printed circuit board) or substrate on which processor 1410 is disposed) of a computing device. In one example, memory devices 1440 can be organized into memory modules 1470. In one example, memory modules 1470 represent dual inline memory modules (DIMMs). In one example, memory modules 1470 represent other organization of multiple memory devices to share at least a portion of access or control circuitry, which can be a separate circuit, a separate device, or a separate board from the host system platform. Memory modules 1470 can include multiple memory devices 1440, and the memory modules can include support for multiple separate channels to the included memory devices disposed on them. In another example, memory devices 1440 may be incorporated into the same package as memory controller 1420, such as by techniques such as multi-chip-module (MCM), package-on-package, through-silicon via (TSV), or other techniques or combinations. Similarly, in one example, multiple memory devices 1440 may be incorporated into memory modules 1470, which themselves may be incorporated into the same package as memory controller 1420. It will be appreciated that for these and other implementations, memory controller 1420 may be part of host processor 1410.

Memory devices 1440 each include one or more memory arrays 1460. Memory array 1460 represents addressable memory locations or storage locations for data. Typically, memory array 1460 is managed as rows of data, accessed via wordline (rows) and bitline (individual bits within a row) control. Memory array 1460 can be organized as separate channels, ranks, and banks of memory. Channels may refer to independent control paths to storage locations within memory devices 1440. Ranks may refer to common locations across multiple memory devices (e.g., same row addresses within different devices) in parallel. Banks may refer to sub-arrays of memory locations within a memory device 1440. In one example, banks of memory are divided into sub-banks with at least a portion of shared circuitry (e.g., drivers, signal lines, control logic) for the sub-banks, allowing separate addressing and access. It will be understood that channels, ranks, banks, sub-banks, bank groups, or other organizations of the memory locations, and combinations of the organizations, can overlap in their application to physical resources. For example, the same physical memory locations can be accessed over a specific channel as a specific bank, which can also belong to a rank. Thus, the organization of memory resources will be understood in an inclusive, rather than exclusive, manner.

In one example, memory devices 1440 include one or more registers 1444. Register 1444 represents one or more storage devices or storage locations that provide configuration or settings for the operation of the memory device. In one example, register 1444 can provide a storage location for memory device 1440 to store data for access by memory controller 1420 as part of a control or management operation. In one example, register 1444 includes one or more Mode Registers. In one example, register 1444 includes one or more multipurpose registers. The configuration of locations within register 1444 can configure memory device 1440 to operate in different “modes,” where command information can trigger different operations within memory device 1440 based on the mode. Additionally or in the alternative, different modes can also trigger different operation from address information or other signal lines depending on the mode. Settings of register 1444 can indicate configuration for I/O settings (e.g., timing, termination or ODT (on-die termination) 1446, driver configuration, or other I/O settings).

In one example, memory device 1440 includes ODT 1446 as part of the interface hardware associated with I/O 1442. ODT 1446 can be configured as mentioned above, and provide settings for impedance to be applied to the interface to specified signal lines. In one example, ODT 1446 is applied to DQ signal lines. In one example, ODT 1446 is applied to command signal lines. In one example, ODT 1446 is applied to address signal lines. In one example, ODT 1446 can be applied to any combination of the preceding. The ODT settings can be changed based on whether a memory device is a selected target of an access operation or a non-target device. ODT 1446 settings can affect the timing and reflections of signaling on the terminated lines. Careful control over ODT 1446 can enable higher-speed operation with improved matching of applied impedance and loading. ODT 1446 can be applied to specific signal lines of I/O interface 1442, 1422 (for example, ODT for DQ lines or ODT for CA lines), and is not necessarily applied to all signal lines.

Memory device 1440 includes controller 1450, which represents control logic within the memory device to control internal operations within the memory device. For example, controller 1450 decodes commands sent by memory controller 1420 and generates internal operations to execute or satisfy the commands. Controller 1450 can be referred to as an internal controller, and is separate from memory controller 1420 of the host. Controller 1450 can determine what mode is selected based on register 1444, and configure the internal execution of operations for access to memory resources 1460 or other operations based on the selected mode. Controller 1450 generates control signals to control the routing of bits within memory device 1440 to provide a proper interface for the selected mode and direct a command to the proper memory locations or addresses. Controller 1450 includes command logic 1452, which can decode command encoding received on command and address signal lines. Thus, command logic 1452 can be or include a command decoder. With command logic 1452, memory device can identify commands and generate internal operations to execute requested commands.

Referring again to memory controller 1420, memory controller 1420 includes command (CMD) logic 1424, which represents logic or circuitry to generate commands to send to memory devices 1440. The generation of the commands can refer to the command prior to scheduling, or the preparation of queued commands ready to be sent. Generally, the signaling in memory subsystems includes address information within or accompanying the command to indicate or select one or more memory locations where the memory devices should execute the command. In response to scheduling of transactions for memory device 1440, memory controller 1420 can issue commands via I/O 1422 to cause memory device 1440 to execute the commands. In one example, controller 1450 of memory device 1440 receives and decodes command and address information received via I/O 1442 from memory controller 1420. Based on the received command and address information, controller 1450 can control the timing of operations of the logic and circuitry within memory device 1440 to execute the commands. Controller 1450 is responsible for compliance with standards or specifications within memory device 1440, such as timing and signaling requirements. Memory controller 1420 can implement compliance with standards or specifications by access scheduling and control.

Memory controller 1420 includes scheduler 1430, which represents logic or circuitry to generate and order transactions to send to memory device 1440. From one perspective, the primary function of memory controller 1420 could be said to schedule memory access and other transactions to memory device 1440. Such scheduling can include generating the transactions themselves to implement the requests for data by processor 1410 and to maintain integrity of the data (e.g., such as with commands related to refresh). Transactions can include one or more commands, and result in the transfer of commands or data or both over one or multiple timing cycles such as clock cycles or unit intervals. Transactions can be for access such as read or write or related commands or a combination, and other transactions can include memory management commands for configuration, settings, data integrity, or other commands or a combination.

Memory controller 1420 typically includes logic such as scheduler 1430 to allow selection and ordering of transactions to improve performance of system 1400. Thus, memory controller 1420 can select which of the outstanding transactions should be sent to memory device 1440 in which order, which is typically achieved with logic much more complex that a simple first-in first-out algorithm. Memory controller 1420 manages the transmission of the transactions to memory device 1440, and manages the timing associated with the transaction. In one example, transactions have deterministic timing, which can be managed by memory controller 1420 and used in determining how to schedule the transactions with scheduler 1430.

In one example, memory controller 1420 includes refresh (REF) logic 1426. Refresh logic 1426 can be used for memory resources that are volatile and need to be refreshed to retain a deterministic state. In one example, refresh logic 1426 indicates a location for refresh, and a type of refresh to perform. Refresh logic 1426 can trigger self-refresh within memory device 1440, or execute external refreshes which can be referred to as auto refresh commands) by sending refresh commands, or a combination. In one example, controller 1450 within memory device 1440 includes refresh logic 1454 to apply refresh within memory device 1440. In one example, refresh logic 1454 generates internal operations to perform refresh in accordance with an external refresh received from memory controller 1420. Refresh logic 1454 can determine if a refresh is directed to memory device 1440, and what memory resources 1460 to refresh in response to the command.

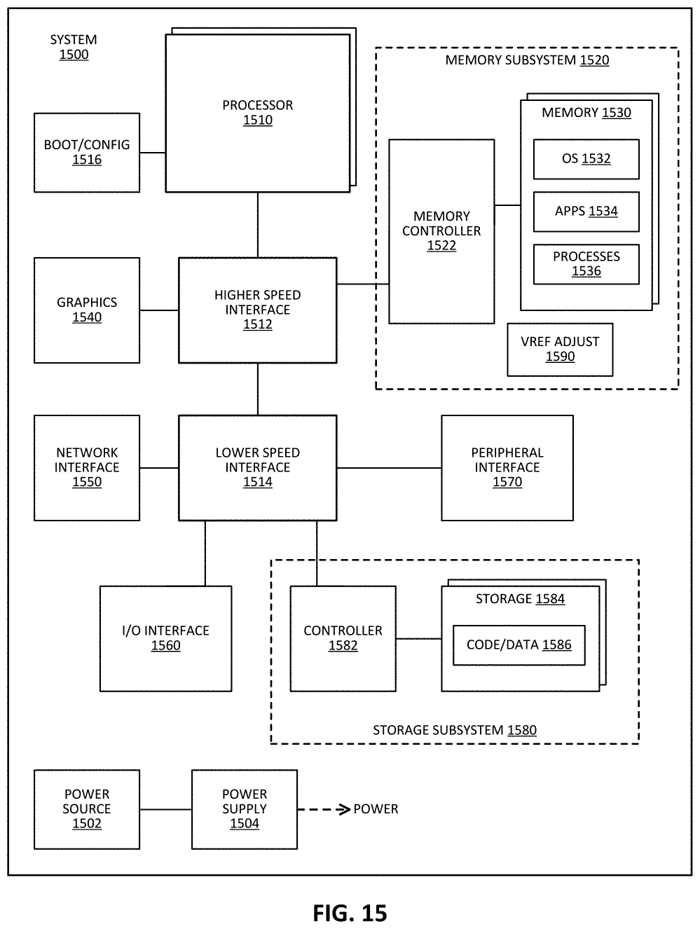

FIG. 15 is a block diagram of an example of a computing system in which training upper and lower data eyes separately can be implemented. System 1500 represents a computing device in accordance with any example herein, and can be a laptop computer, a desktop computer, a tablet computer, a server, a gaming or entertainment control system, embedded computing device, or other electronic device.

System 1500 includes memory subsystem 1520, which can be a system in accordance with an example of system 100 or system 300. In one example, system 1500 can separately train the different data eyes of a PAM signaling system. VREF adjust 1590 represents components to generate training sequences and separately determine the Vref levels for the different data eyes. VREF adjust 1590 can include components in memory controller 1522 and components in memory 1530. VREF adjust 1590 can train the PHYs for the two devices, to set the VREF offsets in accordance with any example described.

System 1500 includes processor 1510 can include any type of microprocessor, central processing unit (CPU), graphics processing unit (GPU), processing core, or other processing hardware, or a combination, to provide processing or execution of instructions for system 1500. Processor 1510 can be a host processor device. Processor 1510 controls the overall operation of system 1500, and can be or include, one or more programmable general-purpose or special-purpose microprocessors, digital signal processors (DSPs), programmable controllers, application specific integrated circuits (ASICs), programmable logic devices (PLDs), or a combination of such devices.

System 1500 includes boot/config 1516, which represents storage to store boot code (e.g., basic input/output system (BIOS)), configuration settings, security hardware (e.g., trusted platform module (TPM)), or other system level hardware that operates outside of a host OS. Boot/config 1516 can include a nonvolatile storage device, such as read-only memory (ROM), flash memory, or other memory devices.

In one example, system 1500 includes interface 1512 coupled to processor 1510, which can represent a higher speed interface or a high throughput interface for system components that need higher bandwidth connections, such as memory subsystem 1520 or graphics interface components 1540. Interface 1512 represents an interface circuit, which can be a standalone component or integrated onto a processor die. Interface 1512 can be integrated as a circuit onto the processor die or integrated as a component on a system on a chip. Where present, graphics interface 1540 interfaces to graphics components for providing a visual display to a user of system 1500. Graphics interface 1540 can be a standalone component or integrated onto the processor die or system on a chip. In one example, graphics interface 1540 can drive a high definition (HD) display or ultra high definition (UHD) display that provides an output to a user. In one example, the display can include a touchscreen display. In one example, graphics interface 1540 generates a display based on data stored in memory 1530 or based on operations executed by processor 1510 or both.

Memory subsystem 1520 represents the main memory of system 1500, and provides storage for code to be executed by processor 1510, or data values to be used in executing a routine. Memory subsystem 1520 can include one or more varieties of random-access memory (RAM) such as DRAM, 3DXP (three-dimensional crosspoint), or other memory devices, or a combination of such devices. Memory 1530 stores and hosts, among other things, operating system (OS) 1532 to provide a software platform for execution of instructions in system 1500. Additionally, applications 1534 can execute on the software platform of OS 1532 from memory 1530. Applications 1534 represent programs that have their own operational logic to perform execution of one or more functions. Processes 1536 represent agents or routines that provide auxiliary functions to OS 1532 or one or more applications 1534 or a combination. OS 1532, applications 1534, and processes 1536 provide software logic to provide functions for system 1500. In one example, memory subsystem 1520 includes memory controller 1522, which is a memory controller to generate and issue commands to memory 1530. It will be understood that memory controller 1522 could be a physical part of processor 1510 or a physical part of interface 1512. For example, memory controller 1522 can be an integrated memory controller, integrated onto a circuit with processor 1510, such as integrated onto the processor die or a system on a chip.

While not specifically illustrated, it will be understood that system 1500 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a HyperTransport or industry standard architecture (ISA) bus, a small computer system interface (SCSI) bus, a universal serial bus (USB), or other bus, or a combination.

In one example, system 1500 includes interface 1514, which can be coupled to interface 1512. Interface 1514 can be a lower speed interface than interface 1512. In one example, interface 1514 represents an interface circuit, which can include standalone components and integrated circuitry. In one example, multiple user interface components or peripheral components, or both, couple to interface 1514. Network interface 1550 provides system 1500 the ability to communicate with remote devices (e.g., servers or other computing devices) over one or more networks. Network interface 1550 can include an Ethernet adapter, wireless interconnection components, cellular network interconnection components, USB (universal serial bus), or other wired or wireless standards-based or proprietary interfaces. Network interface 1550 can exchange data with a remote device, which can include sending data stored in memory or receiving data to be stored in memory.

In one example, system 1500 includes one or more input/output (I/O) interface(s) 1560. I/O interface 1560 can include one or more interface components through which a user interacts with system 1500 (e.g., audio, alphanumeric, tactile/touch, or other interfacing). Peripheral interface 1570 can include any hardware interface not specifically mentioned above. Peripherals refer generally to devices that connect dependently to system 1500. A dependent connection is one where system 1500 provides the software platform or hardware platform or both on which operation executes, and with which a user interacts.

In one example, system 1500 includes storage subsystem 1580 to store data in a nonvolatile manner. In one example, in certain system implementations, at least certain components of storage 1580 can overlap with components of memory subsystem 1520. Storage subsystem 1580 includes storage device(s) 1584, which can be or include any conventional medium for storing large amounts of data in a nonvolatile manner, such as one or more magnetic, solid state, NAND, 3DXP, or optical based disks, or a combination. Storage 1584 holds code or instructions and data 1586 in a persistent state (i.e., the value is retained despite interruption of power to system 1500). Storage 1584 can be generically considered to be a “memory,” although memory 1530 is typically the executing or operating memory to provide instructions to processor 1510. Whereas storage 1584 is nonvolatile, memory 1530 can include volatile memory (i.e., the value or state of the data is indeterminate if power is interrupted to system 1500). In one example, storage subsystem 1580 includes controller 1582 to interface with storage 1584. In one example controller 1582 is a physical part of interface 1514 or processor 1510, or can include circuits or logic in both processor 1510 and interface 1514.

Power source 1502 provides power to the components of system 1500. More specifically, power source 1502 typically interfaces to one or multiple power supplies 1504 in system 1500 to provide power to the components of system 1500. In one example, power supply 1504 includes an AC to DC (alternating current to direct current) adapter to plug into a wall outlet. Such AC power can be renewable energy (e.g., solar power) power source 1502. In one example, power source 1502 includes a DC power source, such as an external AC to DC converter. In one example, power source 1502 or power supply 1504 includes wireless charging hardware to charge via proximity to a charging field. In one example, power source 1502 can include an internal battery or fuel cell source.

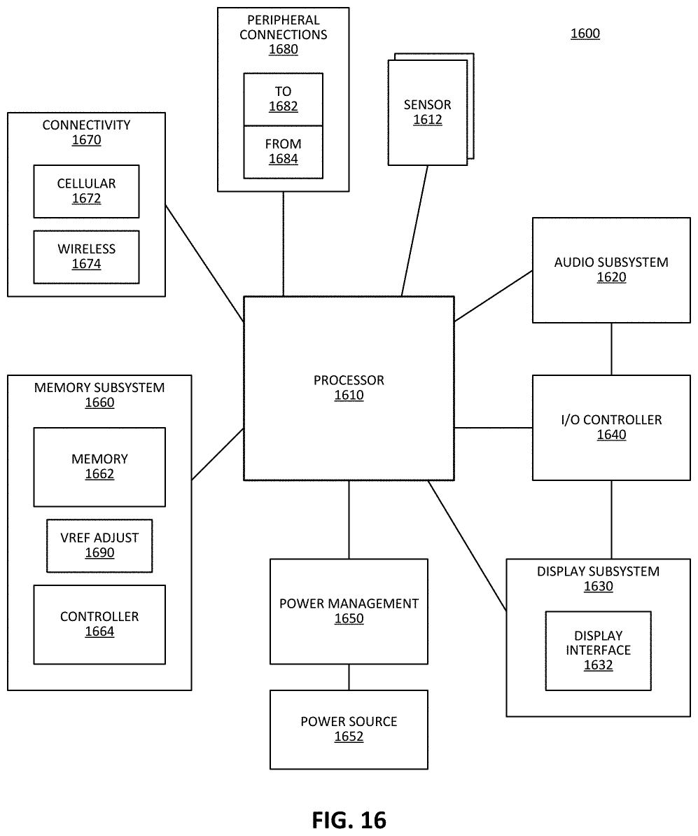

FIG. 16 is a block diagram of an example of a mobile device in which training upper and lower data eyes separately can be implemented. System 1600 represents a mobile computing device, such as a computing tablet, a mobile phone or smartphone, wearable computing device, or other mobile device, or an embedded computing device. It will be understood that certain of the components are shown generally, and not all components of such a device are shown in system 1600.

System 1600 includes memory subsystem 1660, which can be a system in accordance with an example of system 100 or system 300. In one example, system 1600 can separately train the different data eyes of a PAM signaling system. VREF adjust 1690 represents components to generate training sequences and separately determine the Vref levels for the different data eyes. VREF adjust 1690 can include components in controller 1664 and components in memory 1662. VREF adjust 1690 can train the PHYs for the two devices, to set the VREF offsets in accordance with any example described.

System 1600 includes processor 1610, which performs the primary processing operations of system 1600. Processor 1610 can be a host processor device. Processor 1610 can include one or more physical devices, such as microprocessors, application processors, microcontrollers, programmable logic devices, or other processing means. The processing operations performed by processor 1610 include the execution of an operating platform or operating system on which applications and device functions are executed. The processing operations include operations related to I/O (input/output) with a human user or with other devices, operations related to power management, operations related to connecting system 1600 to another device, or a combination. The processing operations can also include operations related to audio I/O, display I/O, or other interfacing, or a combination. Processor 1610 can execute data stored in memory. Processor 1610 can write or edit data stored in memory.

In one example, system 1600 includes one or more sensors 1612. Sensors 1612 represent embedded sensors or interfaces to external sensors, or a combination. Sensors 1612 enable system 1600 to monitor or detect one or more conditions of an environment or a device in which system 1600 is implemented. Sensors 1612 can include environmental sensors (such as temperature sensors, motion detectors, light detectors, cameras, chemical sensors (e.g., carbon monoxide, carbon dioxide, or other chemical sensors)), pressure sensors, accelerometers, gyroscopes, medical or physiology sensors (e.g., biosensors, heart rate monitors, or other sensors to detect physiological attributes), or other sensors, or a combination. Sensors 1612 can also include sensors for biometric systems such as fingerprint recognition systems, face detection or recognition systems, or other systems that detect or recognize user features. Sensors 1612 should be understood broadly, and not limiting on the many different types of sensors that could be implemented with system 1600. In one example, one or more sensors 1612 couples to processor 1610 via a frontend circuit integrated with processor 1610. In one example, one or more sensors 1612 couples to processor 1610 via another component of system 1600.

In one example, system 1600 includes audio subsystem 1620, which represents hardware (e.g., audio hardware and audio circuits) and software (e.g., drivers, codecs) components associated with providing audio functions to the computing device. Audio functions can include speaker or headphone output, as well as microphone input. Devices for such functions can be integrated into system 1600, or connected to system 1600. In one example, a user interacts with system 1600 by providing audio commands that are received and processed by processor 1610.

Display subsystem 1630 represents hardware (e.g., display devices) and software components (e.g., drivers) that provide a visual display for presentation to a user. In one example, the display includes tactile components or touchscreen elements for a user to interact with the computing device. Display subsystem 1630 includes display interface 1632, which includes the particular screen or hardware device used to provide a display to a user. In one example, display interface 1632 includes logic separate from processor 1610 (such as a graphics processor) to perform at least some processing related to the display. In one example, display subsystem 1630 includes a touchscreen device that provides both output and input to a user. In one example, display subsystem 1630 includes a high definition (HD) or ultra-high definition (UHD) display that provides an output to a user. In one example, display subsystem includes or drives a touchscreen display. In one example, display subsystem 1630 generates display information based on data stored in memory or based on operations executed by processor 1610 or both.

I/O controller 1640 represents hardware devices and software components related to interaction with a user. I/O controller 1640 can operate to manage hardware that is part of audio subsystem 1620, or display subsystem 1630, or both. Additionally, I/O controller 1640 illustrates a connection point for additional devices that connect to system 1600 through which a user might interact with the system. For example, devices that can be attached to system 1600 might include microphone devices, speaker or stereo systems, video systems or other display device, keyboard or keypad devices, buttons/switches, or other I/O devices for use with specific applications such as card readers or other devices.

As mentioned above, I/O controller 1640 can interact with audio subsystem 1620 or display subsystem 1630 or both. For example, input through a microphone or other audio device can provide input or commands for one or more applications or functions of system 1600. Additionally, audio output can be provided instead of or in addition to display output. In another example, if display subsystem includes a touchscreen, the display device also acts as an input device, which can be at least partially managed by I/O controller 1640. There can also be additional buttons or switches on system 1600 to provide I/O functions managed by I/O controller 1640.

In one example, I/O controller 1640 manages devices such as accelerometers, cameras, light sensors or other environmental sensors, gyroscopes, global positioning system (GPS), or other hardware that can be included in system 1600, or sensors 1612. The input can be part of direct user interaction, as well as providing environmental input to the system to influence its operations (such as filtering for noise, adjusting displays for brightness detection, applying a flash for a camera, or other features).

In one example, system 1600 includes power management 1650 that manages battery power usage, charging of the battery, and features related to power saving operation. Power management 1650 manages power from power source 1652, which provides power to the components of system 1600. In one example, power source 1652 includes an AC to DC (alternating current to direct current) adapter to plug into a wall outlet. Such AC power can be renewable energy (e.g., solar power, motion based power). In one example, power source 1652 includes only DC power, which can be provided by a DC power source, such as an external AC to DC converter. In one example, power source 1652 includes wireless charging hardware to charge via proximity to a charging field. In one example, power source 1652 can include an internal battery or fuel cell source.

Memory subsystem 1660 includes memory device(s) 1662 for storing information in system 1600. Memory subsystem 1660 can include nonvolatile (state does not change if power to the memory device is interrupted) or volatile (state is indeterminate if power to the memory device is interrupted) memory devices, or a combination. Memory 1660 can store application data, user data, music, photos, documents, or other data, as well as system data (whether long-term or temporary) related to the execution of the applications and functions of system 1600. In one example, memory subsystem 1660 includes memory controller 1664 (which could also be considered part of the control of system 1600, and could potentially be considered part of processor 1610). Memory controller 1664 includes a scheduler to generate and issue commands to control access to memory device 1662.

Connectivity 1670 includes hardware devices (e.g., wireless or wired connectors and communication hardware, or a combination of wired and wireless hardware) and software components (e.g., drivers, protocol stacks) to enable system 1600 to communicate with external devices. The external device could be separate devices, such as other computing devices, wireless access points or base stations, as well as peripherals such as headsets, printers, or other devices. In one example, system 1600 exchanges data with an external device for storage in memory or for display on a display device. The exchanged data can include data to be stored in memory, or data already stored in memory, to read, write, or edit data.

Connectivity 1670 can include multiple different types of connectivity. To generalize, system 1600 is illustrated with cellular connectivity 1672 and wireless connectivity 1674. Cellular connectivity 1672 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, LTE (long term evolution—also referred to as “4G”), 14G, or other cellular service standards. Wireless connectivity 1674 refers to wireless connectivity that is not cellular, and can include personal area networks (such as Bluetooth), local area networks (such as WiFi), or wide area networks (such as WiMax), or other wireless communication, or a combination. Wireless communication refers to transfer of data through the use of modulated electromagnetic radiation through a non-solid medium. Wired communication occurs through a solid communication medium.

Peripheral connections 1680 include hardware interfaces and connectors, as well as software components (e.g., drivers, protocol stacks) to make peripheral connections. It will be understood that system 1600 could both be a peripheral device (“to” 1682) to other computing devices, as well as have peripheral devices (“from” 1684) connected to it. System 1600 commonly has a “docking” connector to connect to other computing devices for purposes such as managing (e.g., downloading, uploading, changing, synchronizing) content on system 1600. Additionally, a docking connector can allow system 1600 to connect to certain peripherals that allow system 1600 to control content output, for example, to audiovisual or other systems.

In addition to a proprietary docking connector or other proprietary connection hardware, system 1600 can make peripheral connections 1680 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), or other type.

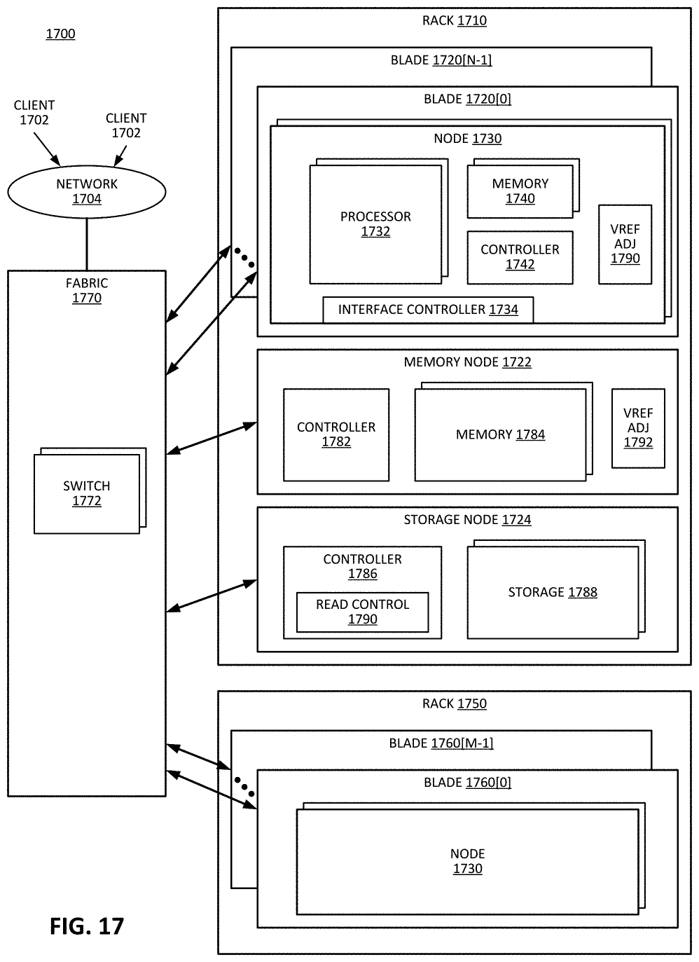

FIG. 17 is a block diagram of an example of a multi-node network in which training upper and lower data eyes separately can be implemented. System 1700 represents a network of nodes that can apply adaptive ECC. In one example, system 1700 represents a data center. In one example, system 1700 represents a server farm. In one example, system 1700 represents a data cloud or a processing cloud.

System 1700 represents a system with storage in accordance with an example of system 100 or system 300. In one example, system 1700 includes memory node 1722 to provide volatile storage for node 1730. In one example, system 1700 can separately train the different data eyes of a PAM signaling system between node 1730 and memory node 1722. VREF adjust 1790 represents components in node 1730 to enable the host to generate training sequences and separately determine the Vref levels for the different data eyes. VREF adjust 1790 can train the host PHY. VREF adjust 1792 represents components in memory node 1722 to enable the memory to either send signals back, such as an error signal, or to separately decode and internally determine its Vref levels for the different data eyes. VREF adjust 1792 can train the memory PHY. VREF adjust 1790 and VREF adjust 1792 can set the VREF offsets in accordance with any example described.

One or more clients 1702 make requests over network 1704 to system 1700. Network 1704 represents one or more local networks, or wide area networks, or a combination. Clients 1702 can be human or machine clients, which generate requests for the execution of operations by system 1700. System 1700 executes applications or data computation tasks requested by clients 1702.

In one example, system 1700 includes one or more racks, which represent structural and interconnect resources to house and interconnect multiple computation nodes. In one example, rack 1710 includes multiple nodes 1730. In one example, rack 1710 hosts multiple blade components, blade 1720[0], . . . , blade 1720[N−1], collectively blades 1720. Hosting refers to providing power, structural or mechanical support, and interconnection. Blades 1720 can refer to computing resources on printed circuit boards (PCBs), where a PCB houses the hardware components for one or more nodes 1730. In one example, blades 1720 do not include a chassis or housing or other “box” other than that provided by rack 1710. In one example, blades 1720 include housing with exposed connector to connect into rack 1710. In one example, system 1700 does not include rack 1710, and each blade 1720 includes a chassis or housing that can stack or otherwise reside in close proximity to other blades and allow interconnection of nodes 1730.

System 1700 includes fabric 1770, which represents one or more interconnectors for nodes 1730. In one example, fabric 1770 includes multiple switches 1772 or routers or other hardware to route signals among nodes 1730. Additionally, fabric 1770 can couple system 1700 to network 1704 for access by clients 1702. In addition to routing equipment, fabric 1770 can be considered to include the cables or ports or other hardware equipment to couple nodes 1730 together. In one example, fabric 1770 has one or more associated protocols to manage the routing of signals through system 1700. In one example, the protocol or protocols is at least partly dependent on the hardware equipment used in system 1700.

As illustrated, rack 1710 includes N blades 1720. In one example, in addition to rack 1710, system 1700 includes rack 1750. As illustrated, rack 1750 includes M blade components, blade 1760[0], . . . , blade 1760[M−1], collectively blades 1760. M is not necessarily the same as N; thus, it will be understood that various different hardware equipment components could be used, and coupled together into system 1700 over fabric 1770. Blades 1760 can be the same or similar to blades 1720. Nodes 1730 can be any type of node and are not necessarily all the same type of node. System 1700 is not limited to being homogenous, nor is it limited to not being homogenous.

The nodes in system 1700 can include compute nodes, memory nodes, storage nodes, accelerator nodes, or other nodes. Rack 1710 is represented with memory node 1722 and storage node 1724, which represent shared system memory resources, and shared persistent storage, respectively. One or more nodes of rack 1750 can be a memory node or a storage node.

Nodes 1730 represent examples of compute nodes. For simplicity, only the compute node in blade 1720[0] is illustrated in detail. However, other nodes in system 1700 can be the same or similar. At least some nodes 1730 are computation nodes, with processor (proc) 1732 and memory 1740. A computation node refers to a node with processing resources (e.g., one or more processors) that executes an operating system and can receive and process one or more tasks. In one example, at least some nodes 1730 are server nodes with a server as processing resources represented by processor 1732 and memory 1740.

Memory node 1722 represents an example of a memory node, with system memory external to the compute nodes. Memory nodes can include controller 1782, which represents a processor on the node to manage access to the memory. The memory nodes include memory 1784 as memory resources to be shared among multiple compute nodes.

Storage node 1724 represents an example of a storage server, which refers to a node with more storage resources than a computation node, and rather than having processors for the execution of tasks, a storage server includes processing resources to manage access to the storage nodes within the storage server. Storage nodes can include controller 1786 to manage access to the storage 1788 of the storage node.

In one example, node 1730 includes interface controller 1734, which represents logic to control access by node 1730 to fabric 1770. The logic can include hardware resources to interconnect to the physical interconnection hardware. The logic can include software or firmware logic to manage the interconnection. In one example, interface controller 1734 is or includes a host fabric interface, which can be a fabric interface in accordance with any example described herein. The interface controllers for memory node 1722 and storage node 1724 are not explicitly shown.

Processor 1732 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory 1740 can be or include memory devices represented by memory 1740 and a memory controller represented by controller 1742.

In general with respect to the descriptions herein, in one aspect, an apparatus includes: a physical interface (PHY) including transceiver circuitry to couple to a data signal line, the data signal line to carry a pulse-amplitude modulation (PAM) signal having a first data eye at a first direct current (DC) offset and a second data eye at a second DC offset; and a control circuit to train the PHY, including to adjust the first DC offset for the first data eye and separately adjust the second DC offset for the second data eye.

In one example of the apparatus, the PAM signal comprises a PAM3 signal having three signal levels and two data eyes. In one example of the apparatus, the PAM signal comprises a PAM4 signal having four signal levels and three data eyes. In accordance with any preceding example of the apparatus, in one example, to adjust the first DC offset and to adjust the second DC offset comprise computation of reference voltage (Vref) training codes. In accordance with any preceding example of the apparatus, in one example, the control circuit is to shmoo a Vref voltage level to compute the Vref training codes. In accordance with any preceding example of the apparatus, in one example, the control circuit is to iteratively train an upper data eye based on a known data pattern, then iteratively train a lower data eye based on a known data pattern, and then provide a pseudorandom binary sequence to test Vref voltage levels for both the upper data eye and the lower data eye. In accordance with any preceding example of the apparatus, in one example, the PHY comprises a PHY of a memory controller. In accordance with any preceding example of the apparatus, in one example, the PHY comprises a PHY of a graphics dynamic random access memory (DRAM) device.

In general with respect to the descriptions herein, in one aspect, a system includes: a memory controller having: a host physical interface (PHY) including transceiver circuitry to couple to a data signal line, the data signal line to carry a pulse-amplitude modulation (PAM) signal having a first host data eye at a first host direct current (DC) offset at the host PHY and a second host data eye at a second host DC offset at the host PHY; a control circuit to train the PHY, including to adjust the first DC offset for the first host data eye and separately adjust the second DC offset for the second host data eye; and a dynamic random access memory (DRAM) device coupled to the memory controller, the DRAM having: a memory physical interface (PHY) including transceiver circuitry to couple to the data signal line to exchange the PAM signal with the memory controller, the PAM signal having a first DRAM data eye at a first DRAM DC offset at the DRAM PHY and a second DRAM data eye at a second DRAM DC offset at the DRAM PHY.

In one example of the system, the PAM signal comprises a PAM3 signal having three signal levels and two data eyes. In one example of the system, the PAM signal comprises a PAM4 signal having four signal levels and three data eyes. In accordance with any preceding example of the system, in one example, the first host DC offset is different in magnitude from the first DRAM DC offset. In accordance with any preceding example of the system, in one example, the second host DC offset is different in magnitude from the second DRAM DC offset. In accordance with any preceding example of the system, in one example, to adjust the first host DC offset and to adjust the second host DC offset comprise computation of reference voltage (Vref) training codes for the host PHY. In accordance with any preceding example of the system, in one example, the control circuit is to shmoo a Vref voltage level to compute the Vref training codes for the host PHY. In accordance with any preceding example of the system, in one example, the control circuit is to iteratively train an upper host data eye based on a known data pattern, then iteratively train a lower host data eye based on a known data pattern, and then provide a pseudorandom binary sequence to test Vref voltage levels for both the upper host data eye and the lower host data eye. In accordance with any preceding example of the system, in one example, to adjust the first DRAM DC offset and to adjust the second DRAM DC offset comprise computation of reference voltage (Vref) training codes for the DRAM PHY. In accordance with any preceding example of the system, in one example, the control circuit is to shmoo a Vref voltage level to compute the Vref training codes for the DRAM PHY. In accordance with any preceding example of the system, in one example, the memory controller is to iteratively send a known data pattern to the DRAM device, and the DRAM device is to reply to the memory controller with error signals, wherein the control circuit of the memory controller is to compute the Vref training codes for the DRAM PHY in response to the error signals. In accordance with any preceding example of the system, in one example, the DRAM device is to receive the known data pattern on a first data (DQ) signal line, and reply to the memory controller with the error signals on a second DQ signal line different from the first DQ signal line. In accordance with any preceding example of the system, in one example, the DRAM device is to receive the known data pattern on a data (DQ) signal line, and reply to the memory controller with the error signals on a loopback signal line associated with the DQ signal line. In accordance with any preceding example of the system, in one example, the control circuit comprises a host control circuit, the DRAM device comprising: a DRAM control circuit to shmoo a Vref voltage level to compute the Vref training codes for the DRAM PHY.

In general with respect to the descriptions herein, in one aspect, a first method includes: training a first data eye of a pulse-amplitude modulation (PAM) signal separately from a second data eye of the PAM signal.

In one example of the first method, the PAM signal comprises a PAM3 signal having three signal levels and two data eyes. In one example of the first method, the PAM signal comprises a PAM4 signal having four signal levels and three data eyes. In accordance with any preceding example of the first method, in one example, the first method includes: generating a known data pattern that applies only to an upper data eye of the PAM signal; sending the known data pattern to a receiver; adjusting a direct current offset for the upper data eye; and iterating the generating, sending, and adjusting until a bit error rate (BER) is within an expected range. In accordance with any preceding example of the first method, in one example, the first method includes: generating a known data pattern that applies only to a lower data eye of the PAM signal; sending the known data pattern to a receiver; adjusting a direct current offset for the lower data eye; and iterating the generating, sending, and adjusting until a bit error rate (BER) is within an expected range. In accordance with any preceding example of the first method, in one example, the first method includes: generating a pseudorandom binary sequence (PRBS); sending the PRBS to a receiver; adjusting an upper data eye or a lower data eye in response to detected data errors; and iterating the generating, sending, and adjusting until a bit error rate (BER) is within an expected range. In accordance with any preceding example of the first method, in one example, adjusting until the BER is within the expected range comprises adjusting a direct current (DC) offset of a reference voltage (Vref) for a host physical interface (PHY). In accordance with any preceding example of the first method, in one example, adjusting until the BER is within the expected range comprises adjusting a direct current (DC) offset of a reference voltage (Vref) for a memory physical interface (PHY).

In general with respect to the descriptions herein, in one aspect, a second method includes: training a first data eye of a pulse-amplitude modulation (PAM) signal separately from a second data eye of the PAM signal, including generating a known data pattern, sending the known data pattern to a memory device, receiving an error signal from the memory device, and sending a training code to the memory device.

In one example of the second method, the PAM signal comprises a PAM3 signal having three signal levels and two data eyes. In one example of the second method, the PAM signal comprises a PAM4 signal having four signal levels and three data eyes. In accordance with any preceding example of the second method, generating the known data pattern comprises generating a known data pattern that applies only to an upper data eye of the PAM signal; and the method includes computing a training code to adjust a direct current offset for the upper data eye in response to the error signal. In accordance with any preceding example of the second method, generating the known data pattern comprises generating a known data pattern that applies only to a lower data eye of the PAM signal; and the method includes computing a training code to adjust a direct current offset for the lower data eye in response to the error signal. In accordance with any preceding example of the second method, in one example, the second method includes: generating a pseudorandom binary sequence (PRBS); sending the PRBS to the memory device; wherein the computing the training code comprises computing the training code in response to detection of errors in an upper data eye or a lower data eye. In accordance with any preceding example of the second method, in one example, computing the training code comprises generating a code to set a direct current (DC) offset of a reference voltage (Vref) for a host physical interface (PHY). In accordance with any preceding example of the second method, in one example, computing the training code comprises generating a code to set a direct current (DC) offset of a reference voltage (Vref) for the memory physical interface (PHY).

In general with respect to the descriptions herein, in one aspect, a third method includes: training a first data eye of a pulse-amplitude modulation (PAM) signal separately from a second data eye of the PAM signal, including receiving a signal from a host at a memory device, determining if the signal matches a known data pattern, sending an error signal from the memory device to the host, and receiving a training code from the host.

In one example of the third method, the PAM signal comprises a PAM3 signal having three signal levels and two data eyes. In one example of the third method, the PAM signal comprises a PAM4 signal having four signal levels and three data eyes. In accordance with any preceding example of the third method, the known data pattern comprises a known data pattern that applies only to an upper data eye of the PAM signal; and the training code comprises a training code to set a direct current offset for the upper data eye in response to the error signal. In accordance with any preceding example of the third method, the known data pattern comprises a known data pattern that applies only to a lower data eye of the PAM signal; and the training code comprises a training code to set a direct current offset for the lower data eye in response to the error signal. In accordance with any preceding example of the third method, in one example, the third method includes: receiving a pseudorandom binary sequence (PRBS) at the memory device from the host; sending the received PRBS signal from the memory device back to the host; wherein the computing the training code comprises computing the training code in response to detection of errors in an upper data eye or a lower data eye of the PRBS signal. In accordance with any preceding example of the third method, in one example, computing the training code comprises generating a code to set a direct current (DC) offset of a reference voltage (Vref) for a host physical interface (PHY). In accordance with any preceding example of the third method, in one example, computing the training code comprises generating a code to set a direct current (DC) offset of a reference voltage (Vref) for the memory physical interface (PHY).

In general with respect to the descriptions herein, in one aspect, an second apparatus includes: a physical interface (PHY) including transceiver circuitry to couple to a data signal line, the data signal line to carry a pulse-amplitude modulation (PAM) signal having a first data eye at a first voltage reference (Vref) level and a second data eye at a second Vref level; and a control circuit to train the PHY, including to adjust the first Vref level for the first data eye and separately adjust the second Vref level for the second data eye.

In one example of the second apparatus, the PAM signal comprises a PAM3 signal having three signal levels and two data eyes. In one example of the second apparatus, the PAM signal comprises a PAM4 signal having four signal levels and three data eyes. In accordance with any preceding example of the second apparatus, in one example, to adjust the first Vref level and to adjust the second Vref level comprise computation of reference voltage (Vref) training codes. In accordance with any preceding example of the second apparatus, in one example, the control circuit is to shmoo a Vref voltage level to compute the Vref training codes. In accordance with any preceding example of the second apparatus, in one example, the control circuit is to iteratively train an upper data eye based on a known data pattern, then iteratively train a lower data eye based on a known data pattern, and then provide a pseudorandom binary sequence to test Vref voltage levels for both the upper data eye and the lower data eye. In accordance with any preceding example of the second apparatus, in one example, the PHY comprises a PHY of a memory controller. In accordance with any preceding example of the second apparatus, in one example, the PHY comprises a PHY of a graphics dynamic random access memory (DRAM) device.

In general with respect to the descriptions herein, in one aspect, an second system includes: a memory controller having: a host physical interface (PHY) including transceiver circuitry to couple to a data signal line, the data signal line to carry a pulse-amplitude modulation (PAM) signal having a first host data eye at a first host voltage reference (Vref) level at the host PHY and a second host data eye at a second host Vref level at the host PHY; a control circuit to train the PHY, including to adjust the first Vref level for the first data eye and separately adjust the second Vref level for the second data eye; and a dynamic random access memory (DRAM) device coupled to the memory controller, the DRAM having: a memory physical interface (PHY) including transceiver circuitry to couple to the data signal line to exchange the PAM signal with the memory controller, the PAM signal having a first DRAM data eye at a first DRAM Vref level at the DRAM PHY and a second DRAM data eye at a second DRAM Vref level at the DRAM PHY.

In one example of the second system, the PAM signal comprises a PAM3 signal having three signal levels and two data eyes. In one example of the second system, the PAM signal comprises a PAM4 signal having four signal levels and three data eyes. In accordance with any preceding example of the second system, in one example, the first host DC offset is different in magnitude from the first DRAM Vref level. In accordance with any preceding example of the second system, in one example, the second host DC offset is different in magnitude from the second DRAM Vref level. In accordance with any preceding example of the second system, in one example, to adjust the first host Vref level and to adjust the second host Vref level comprise computation of reference voltage (Vref) training codes for the host PHY. In accordance with any preceding example of the second system, in one example, the control circuit is to shmoo a Vref voltage level to compute the Vref training codes for the host PHY. In accordance with any preceding example of the second system, in one example, the control circuit is to iteratively train an upper host data eye based on a known data pattern, then iteratively train a lower host data eye based on a known data pattern, and then provide a pseudorandom binary sequence to test Vref voltage levels for both the upper host data eye and the lower host data eye. In accordance with any preceding example of the second system, in one example, to adjust the first DRAM Vref level and to adjust the second DRAM Vref level comprise computation of reference voltage (Vref) training codes for the DRAM PHY. In accordance with any preceding example of the second system, in one example, the control circuit is to shmoo a Vref voltage level to compute the Vref training codes for the DRAM PHY. In accordance with any preceding example of the second system, in one example, the memory controller is to iteratively send a known data pattern to the DRAM device, and the DRAM device is to reply to the memory controller with error signals, wherein the control circuit of the memory controller is to compute the Vref training codes for the DRAM PHY in response to the error signals. In accordance with any preceding example of the second system, in one example, the DRAM device is to receive the known data pattern on a first data (DQ) signal line, and reply to the memory controller with the error signals on a second DQ signal line different from the first DQ signal line. In accordance with any preceding example of the second system, in one example, the DRAM device is to receive the known data pattern on a data (DQ) signal line, and reply to the memory controller with the error signals on a loopback signal line associated with the DQ signal line. In accordance with any preceding example of the second system, in one example, the control circuit comprises a host control circuit, the DRAM device comprising: a DRAM control circuit to shmoo a Vref voltage level to compute the Vref training codes for the DRAM PHY.

Flow diagrams as illustrated herein provide examples of sequences of various process actions. The flow diagrams can indicate operations to be executed by a software or firmware routine, as well as physical operations. A flow diagram can illustrate an example of the implementation of states of a finite state machine (FSM), which can be implemented in hardware and/or software. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted; thus, not all implementations will perform all actions.

To the extent various operations or functions are described herein, they can be described or defined as software code, instructions, configuration, and/or data. The content can be directly executable (“object” or “executable” form), source code, or difference code (“delta” or “patch” code). The software content of what is described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

What is claimed is:

1. An apparatus comprising:
a physical interface (PHY) including transceiver circuitry to couple to a data signal line, the data signal line to carry a pulse-amplitude modulation (PAM) signal having a first data eye at a first voltage reference (Vref) level and a second data eye at a second Vref level; and
a control circuit to train the PHY, including to adjust the first Vref level for the first data eye and separately adjust the second Vref level for the second data eye.

2. The apparatus of claim 1, wherein the PAM signal comprises a PAM3 signal having three signal levels and two data eyes.

3. The apparatus of claim 1, wherein to adjust the first Vref level and to adjust the second Vref level comprise computation of reference voltage (Vref) training codes.

4. The apparatus of claim 3, wherein the control circuit is to shmoo a Vref voltage level to compute the Vref training codes.

5. The apparatus of claim 4, wherein the control circuit is to iteratively train an upper data eye based on a known data pattern, then iteratively train a lower data eye based on a known data pattern, and then provide a pseudorandom binary sequence to test Vref voltage levels for both the upper data eye and the lower data eye.

6. The apparatus of claim 1, wherein the PHY comprises a PHY of a memory controller.

7. The apparatus of claim 1, wherein the PHY comprises a PHY of a graphics dynamic random access memory (DRAM) device.

8. A system comprising:
a memory controller having:
a host physical interface (PHY) including transceiver circuitry to couple to a data signal line, the data signal line to carry a pulse-amplitude modulation (PAM) signal having a first host data eye at a first host voltage reference (Vref) level at the host PHY and a second host data eye at a second host Vref level at the host PHY;
a control circuit to train the PHY, including to adjust the first Vref level for the first data eye and separately adjust the second Vref level for the second data eye; and
a dynamic random access memory (DRAM) device coupled to the memory controller, the DRAM having:
a memory physical interface (PHY) including transceiver circuitry to couple to the data signal line to exchange the PAM signal with the memory controller, the PAM signal having a first DRAM data eye at a first DRAM Vref level at the DRAM PHY and a second DRAM data eye at a second DRAM Vref level at the DRAM PHY.

9. The system of claim 8, wherein the PAM signal comprises a PAM3 signal having three signal levels and two data eyes.

10. The system of claim 8, wherein the first host DC offset is different in magnitude from the first DRAM Vref level.

11. The system of claim 8, wherein the second host DC offset is different in magnitude from the second DRAM Vref level.

12. The system of claim 8, wherein to adjust the first host Vref level and to adjust the second host Vref level comprise computation of reference voltage (Vref) training codes for the host PHY.

13. The system of claim 12, wherein the control circuit is to shmoo a Vref voltage level to compute the Vref training codes for the host PHY.

14. The system of claim 13, wherein the control circuit is to iteratively train an upper host data eye based on a known data pattern, then iteratively train a lower host data eye based on a known data pattern, and then provide a pseudorandom binary sequence to test Vref voltage levels for both the upper host data eye and the lower host data eye.

15. The system of claim 8, wherein to adjust the first DRAM Vref level and to adjust the second DRAM Vref level comprise computation of reference voltage (Vref) training codes for the DRAM PHY.

16. The system of claim 15, wherein the control circuit is to shmoo a Vref voltage level to compute the Vref training codes for the DRAM PHY.

17. The system of claim 16, wherein the memory controller is to iteratively send a known data pattern to the DRAM device, and the DRAM device is to reply to the memory controller with error signals, wherein the control circuit of the memory controller is to compute the Vref training codes for the DRAM PHY in response to the error signals.

18. The system of claim 17, wherein the DRAM device is to receive the known data pattern on a first data (DQ) signal line, and reply to the memory controller with the error signals on a second DQ signal line different from the first DQ signal line.

19. The system of claim 17, wherein the DRAM device is to receive the known data pattern on a data (DQ) signal line, and reply to the memory controller with the error signals on a loopback signal line associated with the DQ signal line.

20. The system of claim 15, wherein the control circuit comprises a host control circuit, the DRAM device comprising:
a DRAM control circuit to shmoo a Vref voltage level to compute the Vref training codes for the DRAM PHY.
